(19) United States
(12) Patent Application Publication
(10) Pub. No.: US 2018/0249577 A1
(43) Pub. Date: Aug. 30, 2018

(54) CAPACITOR AND SUBSTRATE MODULE

(71) Applicant: TDK CORPORATION, Tokyo (JP)

(72) Inventor: Tatsuya FUKUNAGA, Tokyo (JP)

(73) Assignee: TDK CORPORATION, Tokyo (JP)

(21) Appl. No.: 15/888,422

(22) Filed: Feb. 5, 2018

(30) Foreign Application Priority Data
Feb. 24, 2017 (JP) 2017-033846

(51) Int. Cl. H05K 1/18; H01G 11/52; H01G 11/26; H01G 11/74

(52) U.S. Cl. CPC H05K 1/181; H01G 11/52; H05K 2201/10015; H01G 11/74; H01G 11/26

(57) ABSTRACT

A capacitor includes a package, a first electrode, a second electrode, a first coupling terminal, a second coupling terminal, and a third coupling terminal. The first electrode and the second electrode face each other and spaced apart from each other to avoid mutual contact. The first electrode and the second electrode are each wound in an eddy shape around a rotational axis inside the package. The first coupling terminal is coupled to the first electrode, and has a part that is led out of the package. The second coupling terminal is coupled to the second electrode, and has a part that is led out of the package. The third coupling terminal is coupled to the second electrode, and has a part that is led out of the package.

### CROSS REFERENCE TO RELATED APPLICATIONS

This application claims the benefit of Japanese Priority Patent Application JP2017-033846 filed on Feb. 24, 2017, the entire contents of which are incorporated herein by reference.

### BACKGROUND

The disclosure relates to a capacitor, and to a substrate module in which the capacitor is mounted on a substrate.

In recent years, a central processing unit (CPU) to be used for an information processor has undergone a higher operating frequency as well as considerably increased current consumption, due to improvement in a processing speed and higher integration. Along with the increased current consumption, an operating voltage has tended to be decreased in order to reduce the current consumption. Consequently, a faster and larger current fluctuation (i.e., noise current) occurs in a power supply that supplies power to the CPU. Thus, it becomes very difficult to suppress a voltage fluctuation in association with the current fluctuation within an allowable value of the power supply. Accordingly, a laminated capacitor as a smoothing capacitor has been frequently used to stabilize the power supply in a manner to be disposed on the periphery of the CPU, with the laminated capacitor being coupled to the power supply. That is, quick charging and discharging have been performed during a faster and transitional fluctuation of a current to thereby supply a current to the CPU from the laminated capacitor, thus suppressing the voltage fluctuation of the power supply. For example, reference is made to Japanese Unexamined Patent Application Publications No. 2001-284170, No. 2001-284171, and No. 2003-168621.

### SUMMARY

Along with a still higher frequency of an operating frequency of CPU as well as a still lower voltage of an operating voltage of the CPU, a current fluctuation becomes faster and becomes larger, thus causing an equivalent series inductance (ESL) of a laminated capacitor itself to largely affect a voltage fluctuation of a power supply. As a result, the ESL inhibits charging and discharging of the laminated capacitor in association with occurrence of the current fluctuation. This makes the voltage fluctuation of the power supply more likely to be larger, thus making it increasingly difficult to address upcoming higher-speed CPUs.

It is desirable to provide a capacitor and a substrate module that make it possible to reduce an equivalent series inductance.

A capacitor according to an example embodiment of the disclosure includes: a package; a first electrode and a second electrode that face each other and spaced apart from each other to avoid mutual contact, the first electrode and the second electrode being each wound in an eddy shape around a rotational axis inside the package; a first coupling terminal coupled to the first electrode and having a part that is led out of the package; a second coupling terminal coupled to the second electrode and having a part that is led out of the package; and a third coupling terminal coupled to the second electrode and having a part that is led out of the package.

A substrate module according to an example embodiment of the disclosure includes: the capacitor according to the example embodiment of the disclosure; and a mounting substrate that includes a first power supply layer and a second power supply layer.

A capacitor according to an example embodiment of the disclosure includes: a package; a first electrode and a second electrode that face each other and spaced apart from each other to avoid mutual contact, the first electrode and the second electrode being each wound in an eddy shape around a rotational axis inside the package; a first coupling terminal coupled to the first electrode and having a part that is led out of the package; a second coupling terminal coupled to the second electrode and having a part that is led out of the package; and a third coupling terminal that is coupled to an intermediate part of the first coupling terminal, and extends from the intermediate part of the first coupling terminal in a direction that is different from an extending direction of the first coupling terminal, the third coupling terminal having a part that is led out of the package after extending from the intermediate part.

A substrate module according to an example embodiment of the disclosure includes: the capacitor according to the example embodiment of the disclosure; and a mounting substrate that includes a first power supply layer and a second power supply layer.

A capacitor according to an example embodiment of the disclosure includes: a package; a first electrode and a second electrode that face each other and spaced apart from each other to avoid mutual contact, the first electrode and the second electrode being each wound in an eddy shape around a rotational axis inside the package; a first coupling terminal coupled to the first electrode and having a part that is led out of the package; a second coupling terminal coupled to the second electrode and having a part that is led out of the package; and a third coupling terminal and a fourth coupling terminal that are coupled to each other inside the package, with a part of the third coupling terminal and a part of the fourth coupling terminal being each led out of the package.

A substrate module according to an example embodiment of the disclosure includes: the capacitor according to the example embodiment of the disclosure; and a mounting substrate that includes a first power supply layer and a second power supply layer.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure.

FIG. 1 is a perspective view of an example of a substrate module according to a comparative example.

FIG. 2 is a cross-sectional view of an example of a cross-sectional configuration of the substrate module taken along a line A-A in FIG. 1.

FIG. 3 is a cross-sectional view of an example of a cross-sectional configuration of the substrate module taken along a line B-B in FIG. 1.

FIG. 4 describes an eddy current generated upon fluctuation of magnetic fluxes, in accordance with Faraday's law.

FIG. 5 is a circuit diagram illustrating an example of an equivalent circuit of the substrate module according to the comparative example.

FIG. 6 is a characteristic diagram illustrating calculation results obtained by a circuit simulator of the example of the equivalent circuit illustrated in FIG. 5.

FIG. 7 is a cross-sectional view of a configuration example of an electrolytic capacitor according to the comparative example.

FIG. 8 is a configuration diagram illustrating a configuration example of an electrolytic capacitor according to the comparative example.

FIG. 9 is a configuration diagram illustrating an example of a basic configuration of an electrolytic capacitor according to a first example embodiment of the disclosure.

FIG. 10 describes a noise current and a loop current that flow in the electrolytic capacitor illustrated in FIG. 9.

FIG. 11 is a conceptual diagram illustrating an example of a coupling mode (i.e., circuit topology) of a main part of the electrolytic capacitor according to the first example embodiment.

FIG. 12 describes an example of the noise current in the electrolytic capacitor according to the first example embodiment.

FIG. 13 describes an example of the noise current and the loop current in the electrolytic capacitor according to the first example embodiment.

FIG. 14 describes an example of the noise current and the loop current in the electrolytic capacitor according to the first example embodiment.

FIG. 15 is a schematic configuration diagram illustrating another example of the electrolytic capacitor according to the first example embodiment.

FIG. 16 is a conceptual diagram illustrating an example of a coupling mode (i.e., circuit topology) of a main part of the electrolytic capacitor illustrated in FIG. 15.

FIG. 17 is a conceptual diagram illustrating an example of a coupling mode (i.e., circuit topology) of the main part of the electrolytic capacitor illustrated in FIG. 15.

FIG. 18 describes a closed conductor loop formed by the electrolytic capacitor illustrated in FIG. 15.

FIG. 19 is a configuration diagram illustrating an example of coupling positions, in one embodiment, of respective coupling terminals in the electrolytic capacitor illustrated in FIG. 9.

FIG. 20 describes an example of coupling positions of a main part of the electrolytic capacitor illustrated in FIG. 19.

FIG. 21 is a cross-sectional view of a first example of a substrate module according to the first example embodiment.

FIG. 22 is a cross-sectional view of a second example of the substrate module according to the first example embodiment.

FIG. 23 is a conceptual diagram illustrating an example of a coupling mode (i.e., circuit topology) of the main part of the electrolytic capacitor according to the first example embodiment.

FIG. 24 is a schematic configuration diagram illustrating another example of the electrolytic capacitor according to the first example embodiment.

FIG. 25 is a conceptual diagram illustrating an example of a coupling mode (i.e., circuit topology) of a main part of the electrolytic capacitor illustrated in FIG. 24.

FIG. 26 is a cross-sectional view of an example of a substrate module mounted with the electrolytic capacitor illustrated in FIGS. 24 and 25.

FIG. 27 is a conceptual diagram illustrating a modification example of the electrolytic capacitor illustrated in FIGS. 15 and 16.

FIG. 28 is a conceptual diagram illustrating a modification example of the electrolytic capacitor illustrated in FIGS. 24 and 25.

FIG. 29 is a conceptual diagram illustrating a modification example of the electrolytic capacitor illustrated in FIGS. 24 and 25.

FIG. 30 is a conceptual diagram illustrating an example of a coupling mode (i.e., circuit topology) of a main part of an electrolytic capacitor according to a second example embodiment.

FIG. 31 is a schematic configuration diagram illustrating an example of the electrolytic capacitor according to the second example embodiment.

FIG. 32 is a conceptual diagram illustrating an example of a coupling mode (i.e., circuit topology) of a main part of the electrolytic capacitor illustrated in FIG. 31.

FIG. 33 is a cross-sectional view of an example of a substrate module mounted with the electrolytic capacitor illustrated in FIGS. 31 and 32.

FIG. 34 is a conceptual diagram illustrating an example of a coupling mode (i.e., circuit topology) of the main part of the electrolytic capacitor according to the second example embodiment.

FIG. 35 is a schematic configuration diagram illustrating another example of the electrolytic capacitor according to the second example embodiment.

FIG. 36 is a conceptual diagram illustrating an example of a coupling mode (i.e., circuit topology) of a main part of the electrolytic capacitor illustrated in FIG. 35.

FIG. 37 is a cross-sectional view of an example of a substrate module mounted with the electrolytic capacitor illustrated in FIGS. 35 and 36.

FIG. 38 is a conceptual diagram illustrating a modification example of the electrolytic capacitor illustrated in FIGS. 31 and 32.

FIG. 39 is a conceptual diagram illustrating a modification example of the electrolytic capacitor illustrated in FIGS. 35 and 36.

FIG. 40 is a conceptual diagram illustrating an example of a coupling mode (i.e., circuit topology) of a main part of an electrolytic capacitor according to a third example embodiment.

FIG. 41 describes a closed conductor loop formed by the electrolytic capacitor illustrated in FIG. 40.

FIG. 42 is a schematic configuration diagram illustrating an example of the electrolytic capacitor according to the third example embodiment.

FIG. 43 is a cross-sectional view of an example of a substrate module mounted with the electrolytic capacitor illustrated in FIGS. 40 and 42.

FIG. 44 is a conceptual diagram illustrating a modification example of the electrolytic capacitor illustrated in FIG. 40.

### DETAILED DESCRIPTION

Some embodiments of the disclosure are described below in detail with reference to the accompanying drawings.

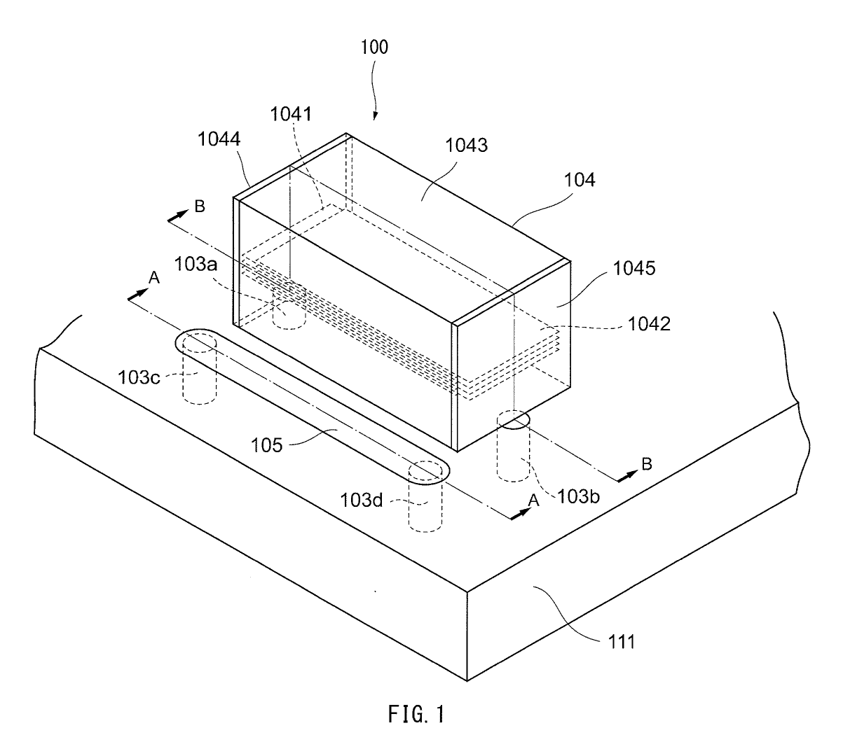

It is to be noted that the following description is directed to illustrative examples of the technology and not to be construed as limiting to the technology. Factors including, without limitation, numerical values, shapes, materials, components, positions of the components, and how the components are coupled to each other are illustrative only and not to be construed as limiting to the technology. Further, elements in the following example embodiments which are not recited in a most-generic independent claim of the technology are optional and may be provided on an as-needed basis. The drawings are schematic and are not intended to be drawn to scale. It is to be noted that the like elements are denoted with the same reference numerals, and any redundant description thereof will not be described in detail. It is to be noted that the description is given in the following order.
0. Comparative Example (FIGS. 1 to 8)

0.1 Outline of Capacitor and Substrate Module according to Comparative Example

0.2 Outline of Electrolytic Capacitor according to Comparative Example

0.3 Details on Electrolytic Capacitor according to Comparative Example

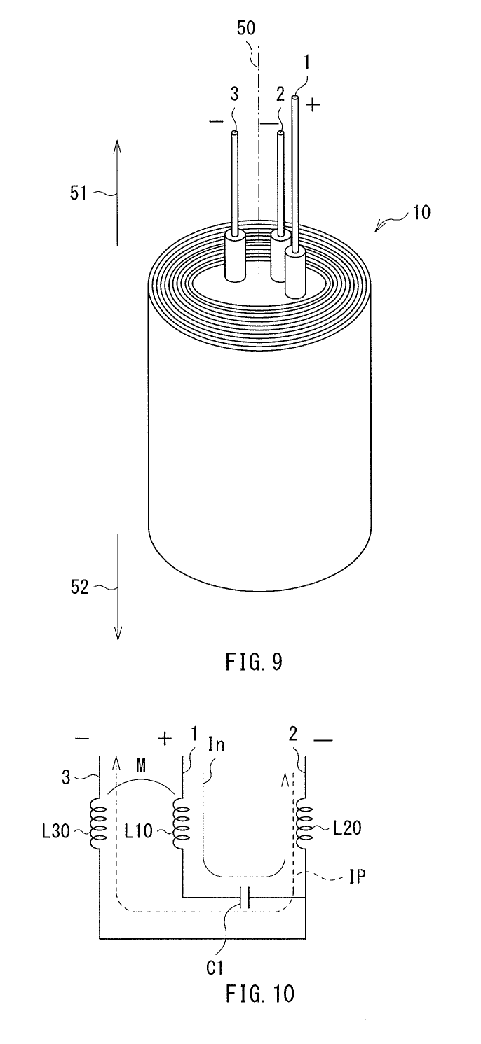

### 1. First Example Embodiment (FIGS. 9 to 29)

### 2. Second Example Embodiment (FIGS. 30 to 39)

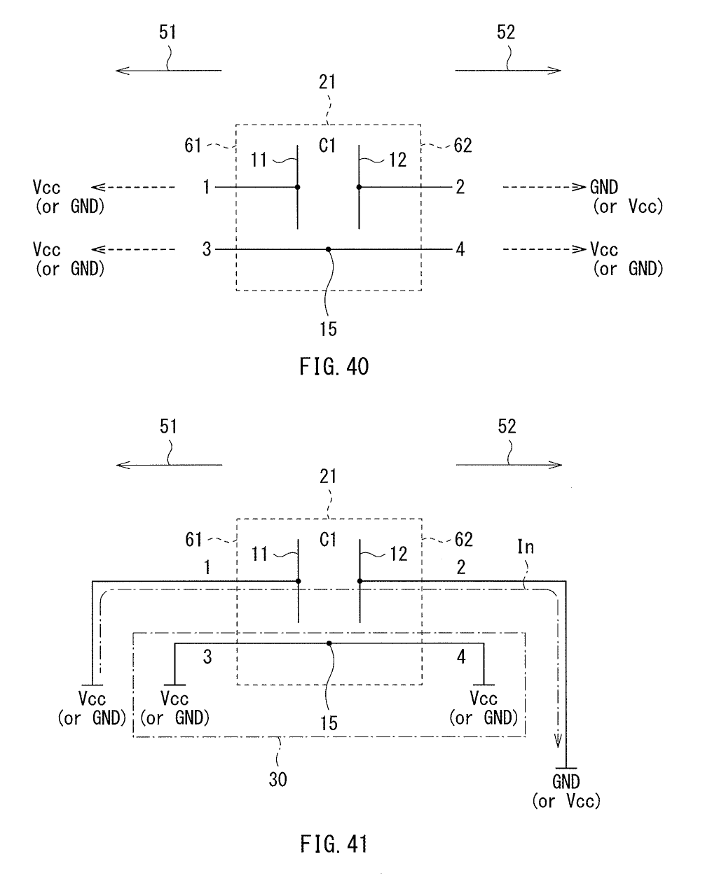

### 3. Third Example Embodiment (FIGS. 40 to 44)

### 4. Other Example Embodiments

### 0. Comparative Example

### [0.1 Outline of Capacitor and Substrate Module According to Comparative Example]

Japanese Unexamined Patent Application Publications No. 2001-284170, No. 2001-284171, and No. 2003-168621 each propose a laminated capacitor in which low ESL is achieved. In the laminated capacitor disclosed in each of the above-mentioned Japanese Unexamined Patent Application Publications, an internal electrode and a side surface terminal are disposed to allow currents flowing in adjacent terminal electrodes to flow in opposite directions. This causes mutual inductance to be negative, and reduces a parasitic inductor component of the capacitor, thus achieving the low ESL.

The technique disclosed in each of the above-mentioned Japanese Unexamined Patent Application Publications is directed to reducing a parasitic inductance of a simple capacitor element. In fact, however, an inductance of a wiring line of a mounting substrate, other than the inductance of the capacitor, also constitutes a factor of inhibiting suppression of a voltage fluctuation of a power supply.

In view of the above-described circumstances, description is given, with reference to FIGS. 1 to 6, of an example of an electronic circuit substrate (i.e., a substrate module) according to a comparative example. The electronic circuit substrate according to the comparative example is able to reduce an equivalent series inductance that is a parasitic inductance of a capacitor or an inductance of a wiring line of a mounting substrate.

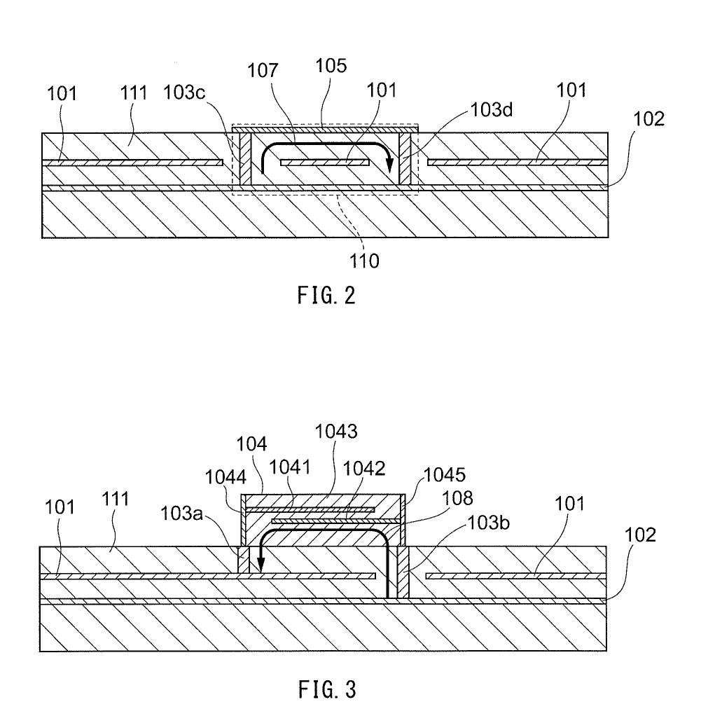

FIG. 1 illustrates an example of a substrate module 100 according to a comparative example. FIG. 2 illustrates an example of a cross-sectional configuration of the substrate module 100 taken along a line A-A in FIG. 1. FIG. 3 illustrates an example of a cross-sectional configuration of the substrate module 100 taken along a line B-B in FIG. 1. As illustrated in FIGS. 1 to 3, the substrate module 100 includes a mounting substrate 111 and a capacitor 104. The mounting substrate 111 includes a ground layer 101 and a DC power supply layer 102. The capacitor 104 is coupled to the ground layer 101 and the DC power supply layer 102, respectively, through wiring lines 103a and 103b of the mounting substrate 111. The capacitor 104 is mounted on a surface of the mounting substrate 111.

The capacitor 104 includes a plurality of first internal electrodes 1041 and a plurality of second internal electrodes 1042. Each of the plurality of first internal electrodes 1041 and each of the plurality of second internal electrodes 1042 are laminated on top of the other, with a dielectric 1043 being interposed therebetween. The capacitor 104 includes a first terminal electrode 1044 and a second terminal electrode 1045. The plurality of first internal electrodes 1041 are each coupled to the first terminal electrode 1044, and the plurality of second internal electrodes 1042 are each coupled to the second terminal electrode 1045. The first terminal electrode 1044 is coupled to the ground layer 101 via the wring line 103a. The second terminal electrode 1045 is coupled to the DC power supply layer 102 via the wring line 103b.

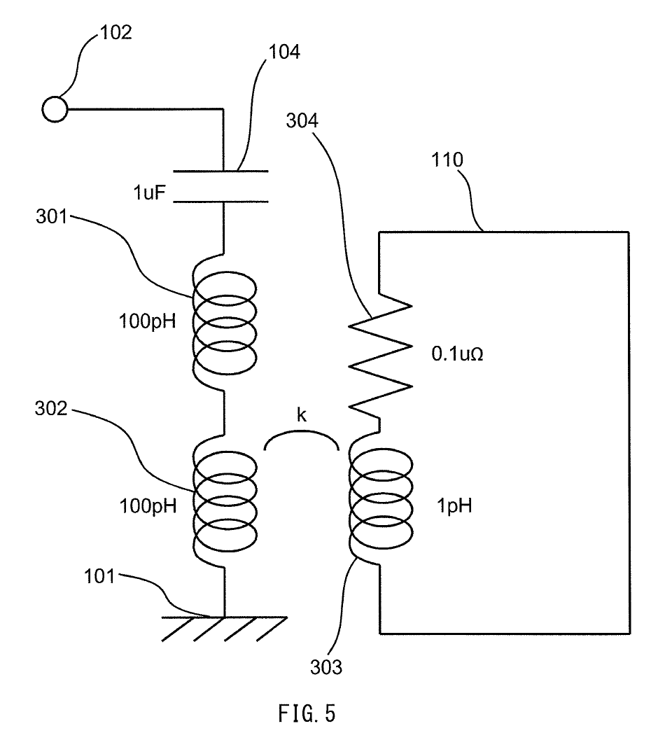

As illustrated in an equivalent circuit diagram of FIG. 5, this configuration allows (a capacitive component of) the capacitor 104, a first inductor 301, and a second inductor 302 to be coupled in series between the DC power supply layer 102 and the ground layer 101. The first inductor 301 is a parasitic inductor component of the capacitor 104. The second inductor 302 is an inductor component of both of the wiring lines 103a and 103b. It is to be noted that, in FIG. 3, the plurality of first internal electrodes 1041 and the plurality of second internal electrodes 1042 are each simplified, and only a single first internal electrode 1041 and only a single second internal electrode 1042 are illustrated.

As illustrated in FIGS. 1 and 2, the substrate module 100 includes a wiring line pattern 105 that is formed on the surface of the mounting substrate 111. The substrate module 100 includes a closed conductor loop 110. The closed conductor loop 110 is formed by coupling both ends of the wiring line pattern 105 to the DC power supply layer 102 via wiring lines 103c and 103d that are formed inside the mounting substrate 111. As illustrated in FIG. 5, the equivalent circuit of the closed conductor loop 110 is represented by coupling an inductor 303 and a resistor 304 in series in a looped manner. The inductor 303 is an inductor component of the closed conductor loop 110. The resistor 304 is a resistance component of the closed conductor loop 110.

The closed conductor loop 110 is mainly formed inside the mounting substrate 111. Thus, the inductor 303 of the closed conductor loop 110 is coupled to the second inductor 302 that is mainly the inductor component of both of the wiring lines 103a and 103b, via a magnetic field to be generated. This coupling leads to generation of a counter electromotive force, in accordance with Faraday's law, in the closed conductor loop 110 in a manner to inhibit a temporal fluctuation of a magnetic flux generated by a noise current that flows through the wiring lines 103a and 103b. The magnetic flux is caused by an eddy current that is generated by the counter electromotive force in the closed conductor loop 110. The magnetic flux is generated in a manner to inhibit the temporal fluctuation of the magnetic flux generated by the noise current that flows through the wiring lines 103a and 103b. This makes it possible to mainly reduce an inductance (an inductance of an equivalent series inductance) of the second inductor 302 that is the inductor component of both of the wiring lines 103a and 103b.

Description is given below in detail of this principle. An inductance L is defined, using a current I, a magnetic flux density B, an area S, and time T, by the following expression (1).

LdI/dt=−d/dt∫∫B·dS (1)

In accordance with this definition, the inductance is proportional to the temporal fluctuation of the magnetic flux B·dS. Accordingly, it is possible to reduce the inductance by suppressing the temporal fluctuation of the magnetic flux to be generated.

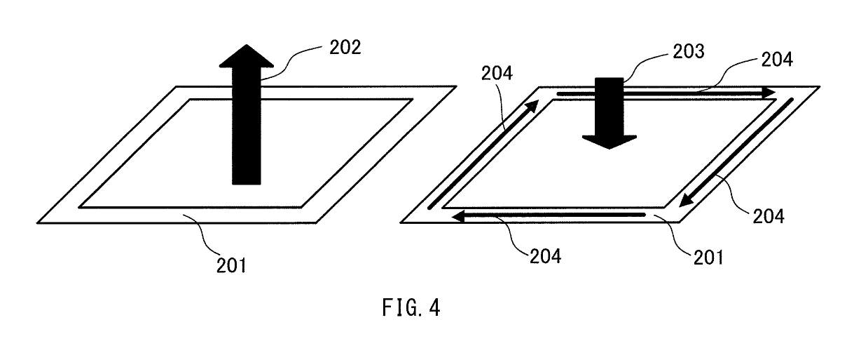

FIG. 4 illustrates a loop conductor 201 that is a closed conductor. When a magnetic flux 202 is generated that penetrates the inside of the loop of the loop conductor 201, a counter electromotive force is generated, in accordance with Faraday's law, in a direction that negates the generated magnetic flux 202. This causes an eddy current 204 to flow into the loop conductor 201, and generates a magnetic flux 203 in a direction opposite to that of the magnetic flux 202, thus suppressing the temporal fluctuation of the magnetic flux.

In FIG. 3, when a noise is generated in the DC power supply layer 102, a noise current 108 passes through the capacitor 104 via the wiring lines 103a and 103b, and flows into the ground layer 101. In this situation, a magnetic flux is generated in a direction perpendicular to the cross-section (i.e., a sheet face in FIG. 3).

As illustrated in FIG. 2, the coupling of both of the wiring line pattern 105 to the DC power supply layer 102 via the wiring lines 103c and 103d allows for formation of the closed conductor loop 110. In accordance with Faraday's law, a counter electromotive force is generated in a direction that inhibits increase in the magnetic flux to be generated by the flow of the noise current 108. This causes an eddy current 107 in a direction opposite to that of the noise current 108 to flow into the closed conductor loop 110, thus suppressing the temporal fluctuation of the magnetic flux to be generated by the noise current 108. A magnetic flux generated by the eddy current 107 negates the magnetic flux, inside the mounting substrate 111, that is generated by the noise current 108. Thus, it is possible to reduce the equivalent series inductance of the second inductor 302 that is the inductor component of both of the wiring lines 103a and 103b of the mounting substrate 111.

As described, the substrate module 100 includes the mounting substrate 111 and the capacitor 104. The mounting substrate 111 includes the ground layer 101 and the DC power supply layer 102. The capacitor 104 is coupled to the ground layer 101 and the DC power supply layer 102, respectively, through the wiring lines 103a and 103b. The capacitor 104 is mounted on the mounting substrate 111. The first inductor 301 and the second inductor 302 are coupled in series. The first inductor 301 is the parasitic inductor component of the capacitor 104. The second inductor 302 is the inductor component of both of the wiring lines 103a and 103b. The substrate module 100 includes the closed conductor loop 110 that is magnetically coupled to the second inductor 302. This allows for magnetic coupling between the second inductor 302 and the closed conductor loop 110, thus causing a counter electromotive force to be generated, in accordance with Faraday's law, in the closed conductor loop 110 in a manner to inhibit the temporal fluctuation of the magnetic flux that corresponds to the inductance of the second inductor 302. This makes it possible to reduce the equivalent series inductance that is the inductance of each of the wiring lines 103a and 103b of the mounting substrate 111.

Moreover, in the substrate module 100, the closed conductor loop 110 is configured by the wiring line patterns (i.e., the wiring lines 103c and 103d, the wiring line pattern 105, and the DC power supply layer 102). The wiring line patterns are formed inside the mounting substrate 111 or on the surface of the mounting substrate 111. Thus, it becomes possible to inhibit the temporal fluctuation of the magnetic flux corresponding to the inductance of the second inductor 302 that is mainly the inductor component of both of the wiring lines 103a and 103b, thus mainly reducing the inductance (i.e., equivalent series inductance) of the wiring lines 103a and 103b of the mounting substrate 111.

In the substrate module 100, a part of the closed conductor loop 110 is the DC power supply layer 102, thus making it possible to remove an unnecessary wiring line by using the DC power supply layer 102 as a part of the closed conductor loop 110.

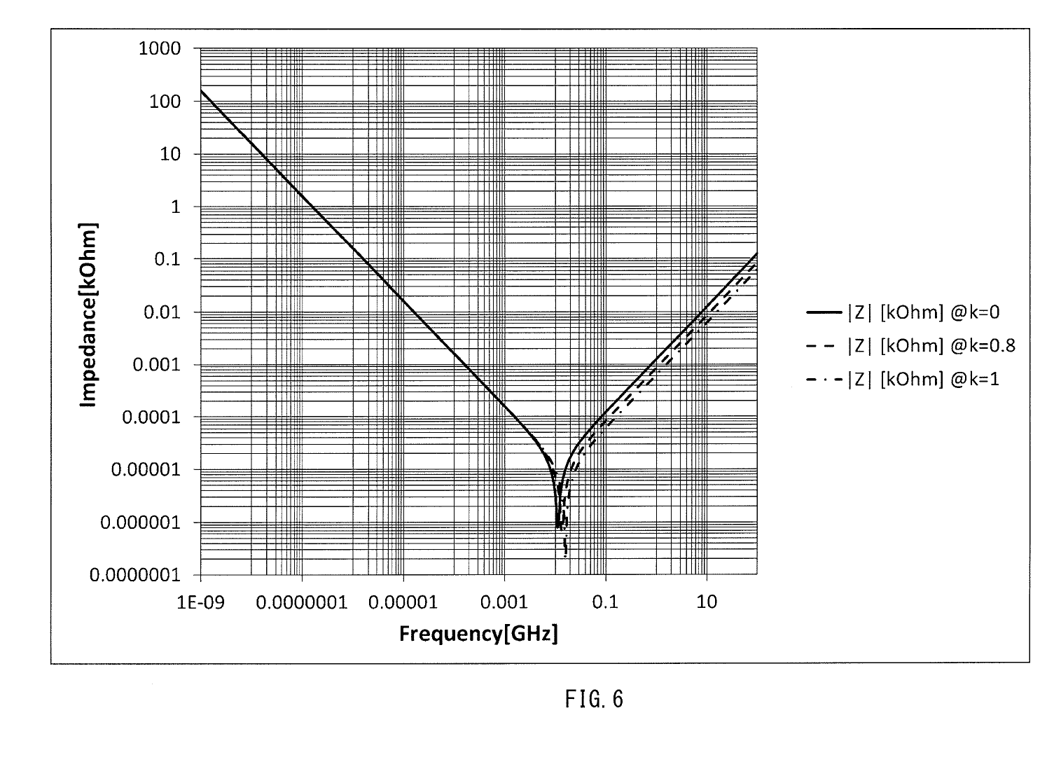

FIG. 5 illustrates, in the substrate module 100, an example of the equivalent circuit in a case of the magnetic coupling between the closed conductor loop 110 and the second inductor 302 provided by both the wiring lines 103a and 103b. The examples of the equivalent circuit include a circuit in which the capacitor 104, the first inductor 301, and the second inductor 302 are coupled in series, and a circuit in which the resistor 304 and the inductor 303 are coupled in series. The capacitor 104 is provided between and coupled, in series, to the DC power supply layer 102 and the ground layer 101. The first inductor 301 is the parasitic inductor of the capacitor 104. The second inductor 302 is a component of the equivalent series inductor of each of the wiring lines 103a and 103b of the mounting substrate 111. The resistor 304 is the resistance component of the closed conductor loop 110 that is formed by the wiring line pattern 105, the wiring lines 103c and 103d of the mounting substrate 111, and the DC power supply layer 102. The inductor 303 is the inductor component of the closed conductor loop 110. The second inductor 302 and the inductor 303 of the closed conductor loop 110 are coupled to each other at a coupling coefficient k. FIG. 6 illustrates calculation results, obtained by a circuit simulator of an impedance between the DC power supply layer 102 and the ground layer 101 of the equivalent circuit, in the example of the equivalent circuit. The calculation was performed under the condition that the capacitor 104 had a capacitance of 1 μF, the first inductor 301 had an inductance of 100 pH, the second inductor 302 had an inductance of 100 pH, the inductor 303 of the closed conductor loop 110 had an inductance of 1 pH, and the resistor 304 had a resistance value of 0.1 μΩ. It is appreciated from FIG. 6 that, as the coupling coefficient k is increased from 0 through 0.8 to 1, the inductance of the equivalent series inductor component between the DC power supply layer 102 and the ground layer 101 is reduced. A case where k is equal to 0 (i.e., k=0) is equivalent to a case where the closed conductor loop 110 is not present. It is found that the presence of the closed conductor loop 110 allows for reduction in the inductance of the equivalent series inductor component between the DC power supply layer 102 and the ground layer 101.

Although, in the above description, the wiring line pattern 105 formed on the surface of the mounting substrate 111 constitutes a part of the closed conductor loop 110, the wiring line pattern 105 may also be formed inside the mounting substrate 111. Further, although, in the above description, both ends of the wiring line pattern 105 are each coupled to the DC power supply layer 102 via the wiring lines 103c and 103d to form the closed conductor loop 110, the closed conductor loop 110 may be formed by coupling both the ends of the wiring line pattern 105 to the ground layer 101 via wiring lines formed inside the mounting substrate 111. Even in this case, effects similar to those of the substrate module 100 are obtained.

Further, the closed conductor loop 110 may be formed by coupling, via the wiring lines formed inside the mounting substrate 111, both the ends of the wiring line pattern 105 to an independent wiring line pattern that is coupled neither to the ground layer 101 nor to the DC power supply layer 102. Insofar as the closed conductor loop is formed, it is possible to reduce the equivalent series inductance that is the inductance of the wiring line of the mounting substrate, using the eddy current 107 generated in accordance with Faraday's law.

Although the description has been given hereinabove referring to the substrate module 100 including a single closed conductor loop 110, there may be a plurality of closed conductor loops that are each coupled to the second inductor 302 via a magnetic field to be generated. For example, two closed conductor loops may be formed to interpose the location where the capacitor 104 is mounted.

### [0.2 Outline of Electrolytic Capacitor According to Comparative Example]

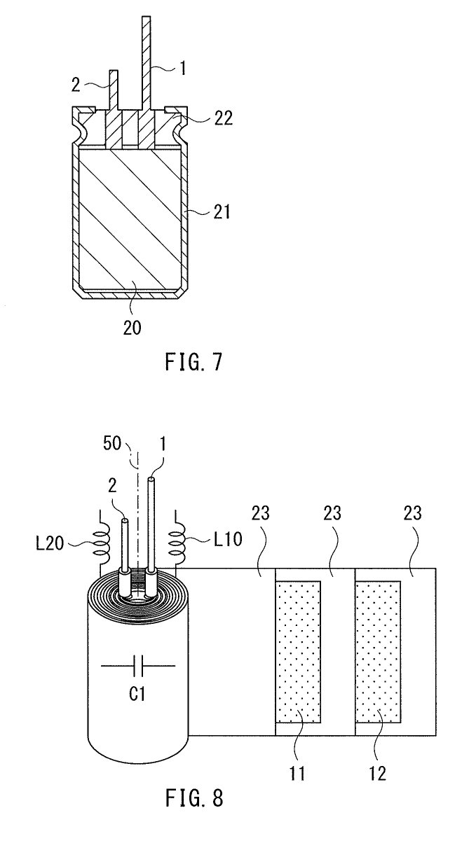

FIGS. 7 and 8 illustrate a configuration example of the electrolytic capacitor according to the comparative example. The electrolytic capacitor according to the comparative example includes a package 21, a capacitor main body 20 disposed inside the package 21, and a sealing member 22 that seals the capacitor main body 20 inside the package 21. The electrolytic capacitor according to the comparative example further includes a first coupling terminal 1 and a second coupling terminal 2 that are each coupled to the capacitor main body 20 via the sealing member 22.

As illustrated in FIG. 8, the capacitor main body 20 includes a first electrode 11, a second electrode 12, and a separator 23. The first electrode 11 and the second electrode 12 are each configured by an aluminum foil, for example. The first electrode 11 serves as a positive electrode, for example, and the second electrode 12 serves as a negative electrode, for example. The separator 23 is configured by an electrolytic sheet, for example.

The first electrode 11 and the second electrode 12 face each other, and are spaced apart with the separator 23 being interposed therebetween, in order to avoid mutual contact. The first electrode 11, the separator 23, and the second electrode 12 are wound in an eddy shape around a rotational axis 50 inside the package 21.

One end of the first coupling terminal 1 is coupled to the first electrode 11, and a part of the first coupling terminal 1 including the other end is led out of the package 21. One end of the second coupling terminal 2 is coupled to the second electrode 12, and a part of the second coupling terminal 2 including the other end is led out of the package 21.

### [0.3 Details on Electrolytic Capacitor According to Comparative Example]

In the electrolytic capacitor according to the comparative example, the capacitor main body 20 forms a capacitor C1. As the parasitic inductor in the electrolytic capacitor according to the comparative example, there are an inductor L10 provided by the first coupling terminal 1 and an inductor L20 provided by the second coupling terminal 2. The electrolytic capacitor according to the comparative example is superior in low-frequency characteristics because of a large capacity of the capacitor C1. On the other hand, high-frequency characteristics may be worse due to a large inductance of each of the parasitic inductors (i.e., the inductors L10 and L20) that are provided, respectively, by the first coupling terminal 1 and the second coupling terminal 2.

What is desired is a development of a technique for such an electrolytic capacitor that reduces the parasitic inductance (i.e., equivalent series inductance) of the electrolytic capacitor by forming the closed conductor loop on the basis of a principle similar to that of the substrate module 100 illustrated in FIGS. 1 to 3.

### 1. First Example Embodiment

Description is given next of the electrolytic capacitor and the substrate module according to the first example embodiment of the disclosure. It is to be noted that, in the following, parts that are substantially the same as the components of the capacitor and the substrate module according to the foregoing comparative example are denoted with the same reference numerals, and descriptions thereof are omitted where appropriate.

The substrate module in any embodiment of the disclosure includes the electrolytic capacitor and the mounting substrate. The mounting substrate includes a first power supply layer and a second power supply layer. Here, one of the first power supply layer and the second power supply layer may be a ground layer GND. The other of the first power supply layer and the second power supply layer may be a DC power supply layer Vcc. Further, two DC power supply layers having different voltages may be included instead of the combination of the ground layer GND and the DC power supply layer Vcc. In this case, one of the first power supply layer and the second power supply layer may be a first DC power supply layer that supplies a first DC voltage. Further, the other of the first power supply layer and the second power supply layer may be a second DC power supply layer that supplies a second DC voltage.

As described above, the power supply layer in any embodiment of the disclosure is limited neither to the ground layer GND nor to the DC power supply layer Vcc. However, in the following first example embodiment, description is given, exemplifying a case where the mounting substrate includes, as the power supply layer, the ground layer GND and the DC power supply layer Vcc. The same holds true also for other example embodiments described later.

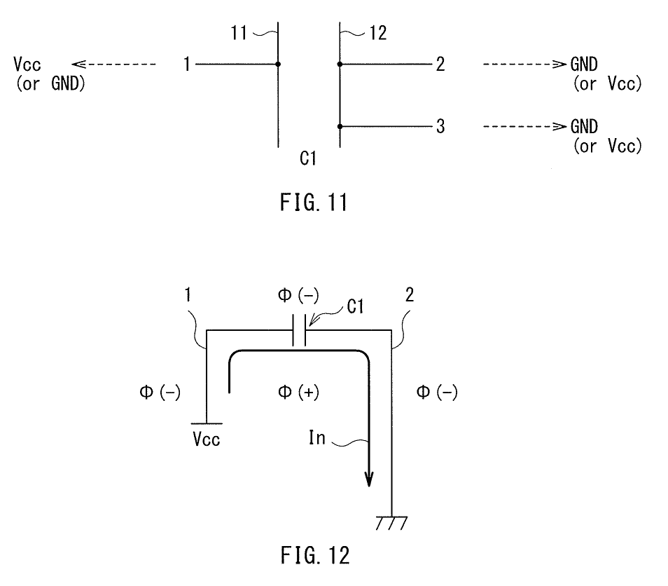

FIG. 9 illustrates an example of a basic configuration of the electrolytic capacitor according to the first example embodiment of the disclosure. FIG. 10 describes a noise current In and a loop current Ip that flow in the electrolytic capacitor illustrated in FIG. 9. FIG. 11 illustrates an example of a coupling mode (i.e., circuit topology) of a main part of the electrolytic capacitor according to the first example embodiment.

The electrolytic capacitor according to the present example embodiment further includes a third coupling terminal 3 in addition to the components of the electrolytic capacitor according to the comparative example.

One end of the third coupling terminal 3 is coupled to the second electrode 12, and a part of the third coupling terminal 3 including the other end is led out of the package 21.

In the configuration example of FIG. 11, a part of the first coupling terminal 1 may be coupleable to one of the first power supply layer and the second power supply layer. A part of the second coupling terminal 2 and a part of the third coupling terminal 3 may be each coupleable to the other of the first power supply layer and the second power supply layer.

For example, as illustrated in FIG. 11, the first coupling terminal 1 may be coupled to one of the ground layer GND and the DC power supply layer Vcc, and the second coupling terminal 2 may be coupled to the other of the ground layer GND and the DC power supply layer Vcc, thereby forming the capacitor C1 between the DC power supply layer Vcc and the ground layer GND.

In the configuration example of FIGS. 9 and 10, in particular, the first coupling terminal 1 may be coupled to plus (+) side (i.e., side of the DC power supply layer Vcc), and the second coupling terminal 2 and the third coupling terminal 3 may be each coupled to minus (−) side (i.e., side of the ground layer GND). As illustrated in FIG. 10, there may be formed the inductor L10 provided by the first coupling terminal 1, the inductor L20 provided by the second coupling terminal 2, and an inductor L30 provided by the third coupling terminal 3. The inductor L10 and the inductor L30 may be magnetically coupled to each other with a mutual inductance M.

For example, as illustrated in FIG. 10, the noise current In may flow through a path of the DC power supply layer Vcc, the inductor L10, the capacitor C1, the inductor L20, and the ground layer GND, in this order. Meanwhile, a closed conductor loop may be formed by the ground layer GND, the inductor L20, the second electrode 12, the inductor L30, and the ground layer GND. This allows for generation of a counter electromotive force in the closed conductor loop in accordance with Faraday's law when the noise current In flows, thus causing the loop current Ip to flow in a direction opposite to that of the noise current In.

As illustrated in FIG. 11, the second coupling terminal 2 and the third coupling terminal 3 may be each coupled to the other of the ground layer GND and the DC power supply layer Vcc. This allows for formation of a closed conductor loop with a path of the ground layer GND (or the DC power supply layer Vcc), the second coupling terminal 2, the second electrode 12, the third coupling terminal 3, and the ground layer GND (or the DC power supply layer Vcc). When the noise current In flows into the capacitor C1, a counter electromotive force is generated in the closed conductor loop in accordance with Faraday's law. This makes it possible to reduce the parasitic inductance (i.e., equivalent series inductance) of the electrolytic capacitor.

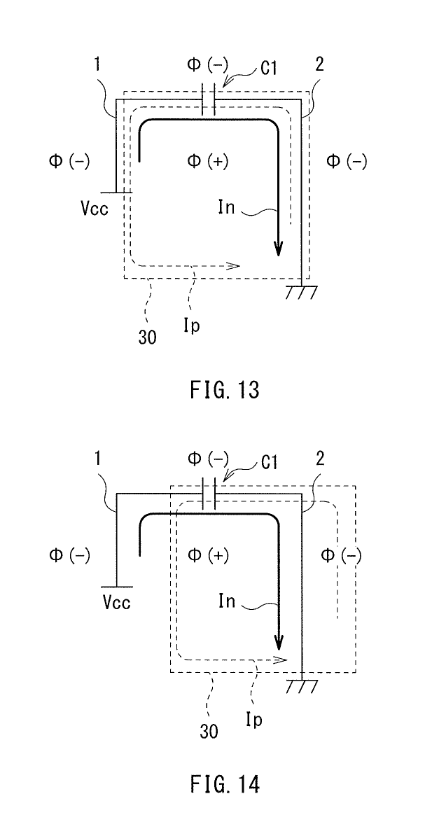

FIG. 12 illustrates an example of the noise current In in the electrolytic capacitor according to the present example embodiment. FIGS. 13 and 14 each illustrate an example of the noise current In and the loop current Ip in the electrolytic capacitor according to the present example embodiment. In FIGS. 12 to 14, symbols Φ(+) and Φ(−) each denote a direction of the magnetic flux caused by the noise current In. The symbol Φ(+) indicates that the magnetic flux propagates in a direction from front side toward rear side of the sheet face. The symbol Φ(−) indicates that the magnetic flux propagates in a direction from rear side toward front side of the sheet face.

Description is given, exemplifying a case where the first coupling terminal 1 is coupled to the DC power supply layer Vcc while the second coupling terminal 2 and the third coupling terminal 3 are each coupled to the ground layer GND. In this case, for example, the noise current In may flow through a path of the DC power supply layer Vcc, the first coupling terminal 1, the capacitor C1, the second coupling terminal 2, and the ground layer GND in this order, as illustrated in FIG. 12.

Meanwhile, as illustrated in FIGS. 13 and 14, formation of a closed conductor loop 30 allows for generation of a counter electromotive force in the closed conductor loop 30 in accordance with Faraday's law, thus causing the loop current Ip to flow in the direction opposite to that of the noise current In. This makes it possible to reduce the parasitic inductance of the electrolytic capacitor. In this case, in order to increase an effect of the closed conductor loop 30 negating the inductance, it is sufficient that leakage flux be decreased and that the coupling coefficient be increased between the closed conductor loop 30 and a path part through which the noise current In flows. As illustrated in FIG. 13, overlapping between the closed conductor loop 30 and the path part through which the noise current In flows is increased, an effect of adding together the magnetic fluxes in the same direction is increased, thus allowing the coupling coefficient to be increased. As illustrated in FIG. 14, when there is less overlapping between the closed conductor loop 30 and the path part through which the noise current In flows, an effect of adding together the magnetic fluxes in the opposite directions is increased, thus causing the coupling coefficient to be decreased.

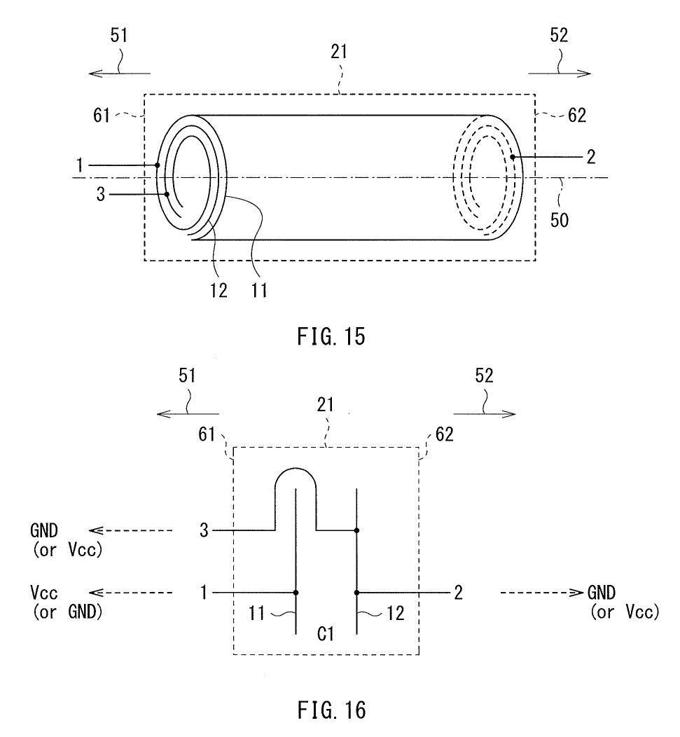

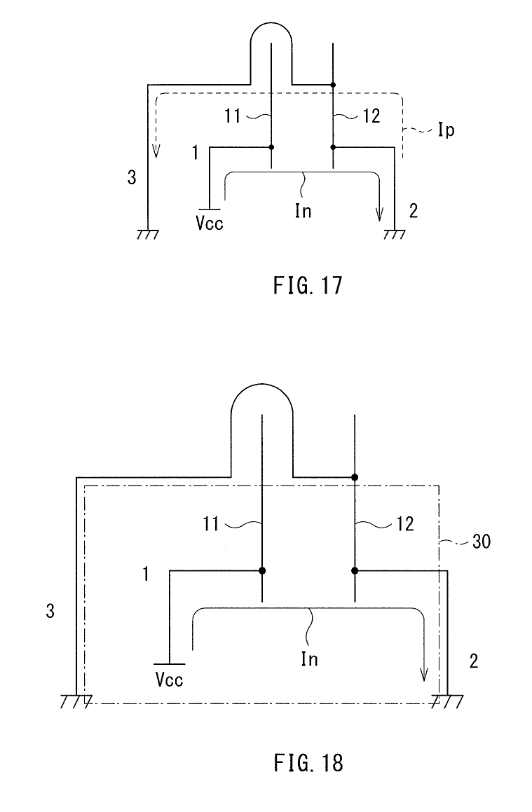

The electrolytic capacitor according to the present example embodiment may have a configuration illustrated in FIG. 15. FIG. 15 schematically illustrates another example of the electrolytic capacitor according to the present example embodiment. FIG. 16 illustrates an example of a coupling mode (i.e., circuit topology) of a main part of the electrolytic capacitor illustrated in FIG. 15. FIG. 17 illustrates an example of a coupling mode (i.e., circuit topology) of the main part of the electrolytic capacitor illustrated in FIG. 15. FIG. 18 illustrates an example of the closed conductor loop 30 formed by the electrolytic capacitor illustrated in FIG. 15.

Here, as illustrated in FIGS. 15 and 16, a first end 61 indicates an end, of the package 21, located in a first direction 51 of the rotational axis 50 as viewed from the inside of the package 21. Further, a second end 62 indicates an end, of the package 21, located in a second direction 52 of the rotational axis 50 as viewed from the inside of the package 21. The second direction 52 is a direction different from the first direction 51. The same holds true also for other configuration examples and other example embodiments that are described later.

In the configuration example of FIGS. 15 to 17, a part of the first coupling terminal 1 and a part of the third coupling terminal 3 may be each led out of the package 21 from the first end 61. Further, a part of the second coupling terminal 2 may be led out of the package 21 from the second end 62.

As illustrated in FIG. 16, a part of the first coupling terminal 1 may be coupleable to one of the first power supply layer and the second power supply layer. A part of the second coupling terminal 2 and a part of the third coupling terminal 3 may be each coupleable to the other of the first power supply layer and the second power supply layer.

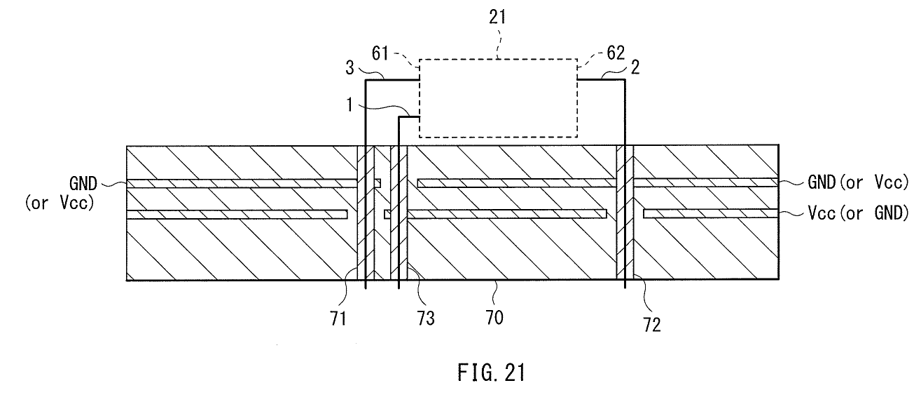

In this configuration example, there is large overlapping area between two loops. One of the two loops may be a loop (i.e., a path of the noise current In) that includes the first coupling terminal 1 led from the first end 61, the first electrode 11, the second electrode 12, and the second coupling terminal 2 led from the second end 62. The other of the two loops may be a closed conductor loop that includes the third coupling terminal 3 led from the first end 61, the second electrode 12, and the second coupling terminal 2 led from the second end 62. The large overlapping area allows for strong coupling between the two loops. This makes it possible to reduce the parasitic inductance of the electrolytic capacitor. In particular, in a case where the electrolytic capacitor is mounted on the mounting substrate 70 as illustrated in FIG. 21 described later, the third coupling terminal 3 may be located close to the first coupling terminal 1, thus making it possible to increase the overlapping area of the two loops.

As illustrated in FIGS. 17 and 18, for example, the first coupling terminal 1 may be coupled to the DC power supply layer Vcc, and the second coupling terminal 2 and the third coupling terminal 3 may be each coupled to the ground layer GND, thus causing the noise current In to flow through the path of the DC power supply layer Vcc, the first coupling terminal 1, the capacitor C1, the second coupling terminal 2, and the ground layer GND, in this order. Meanwhile, a counter electromotive force is generated in accordance with Faraday's law in the closed conductor loop 30 of the ground layer GND, the second coupling terminal 2, the second electrode 12, the first electrode 11, the third coupling terminal 3, and the ground layer GND, thus causing the loop current Ip to flow. Because of the magnetic coupling between the path (i.e., loop) of the noise current In and the closed conductor loop, it is possible to reduce the parasitic inductance of the electrolytic capacitor.

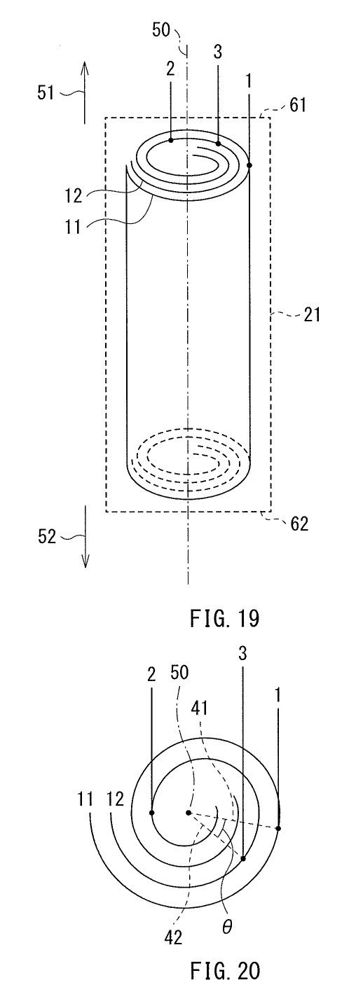

FIG. 19 illustrates an example of coupling positions, in one embodiment, of respective coupling terminals in the electrolytic capacitor illustrated in FIG. 9. FIG. 20 illustrates an example of coupling positions of a main part of the electrolytic capacitor illustrated in FIG. 19.

In the configuration example of FIGS. 19 and 20, all of a part of the first coupling terminal 1, a part of the second coupling terminal 2, and a part of the third coupling terminal 3 may be led out of the package 21 from the first end 61.

FIG. 20 illustrates the package 21 projected onto a plane that is perpendicular to the rotational axis 50, from the infinite distance of the rotational axis 50. In the plane perpendicular to the rotational axis 50, a first line segment 41 indicates a line segment that connects the rotational axis 50 to a position at which the first coupling terminal 1 is coupled to the first electrode 11. Further, a second line segment 42 indicates a line segment that connects the rotational axis 50 to a position at which the third coupling terminal 3 is coupled to the second electrode 12. In one embodiment, θ may range from 0° to 90°, provided that θ denotes a minor angle formed between the first line segment 41 and the second line segment 42. Further, when the package 21 is projected onto the plane that is perpendicular to the rotational axis 50 from the infinite distance of the rotational axis 50, the third coupling terminal 3 may be coupled to a position of the second electrode 12 adjacent, within the range of the angle θ, to the coupling position of the first electrode 11, to which the first coupling terminal 1 is coupled, in one embodiment.

In the configuration example of FIGS. 19 and 20, a loop of the noise current In may be formed. In this loop, the noise current In flows through one of the ground layer GND and the DC power supply layer Vcc, the first coupling terminal 1, the capacitor C1 formed between the first electrode 11 and the second electrode 12, the second coupling terminal 2, and the other of the ground layer GND and the DC power supply layer Vcc. With respect to the loop of the noise current In, the closed conductor loop may be formed by the other of the ground layer GND and the DC power supply layer Vcc, the second coupling terminal 2, the second electrode 12, the third coupling terminal 3, and the other of the ground layer GND and the DC power supply layer Vcc. In this configuration example, by limiting θ within the range from 0° to 90°, it becomes possible to form the closed conductor loop including the third coupling terminal 3 at a position closer to the loop of the noise current In, thus enabling the coupling coefficient between the two loops to be increased. This makes it possible to further reduce the parasitic inductance of the electrolytic capacitor.

Further, by coupling the third coupling terminal 3 to a position of the second electrode 12 adjacent, within the range of the angle θ, to the coupling position of the first electrode 11, to which the first coupling terminal 1 is coupled, it becomes possible to form the closed conductor loop including the third coupling terminal 3 at a position closer to the loop of the noise current In. This enables the coupling coefficient between the two loops to be further increased. Consequently, it becomes possible to further reduce the parasitic inductance of the electrolytic capacitor.

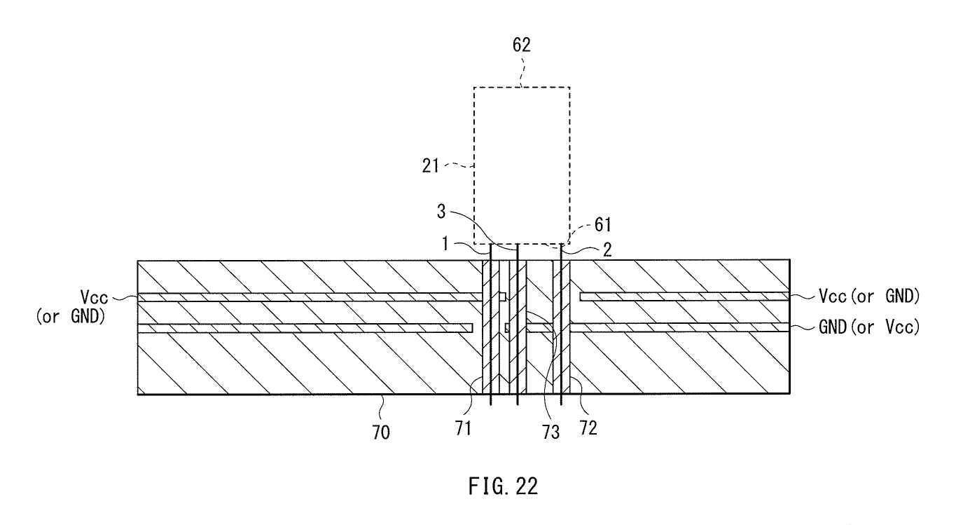

FIG. 21 illustrates a first example of the substrate module according to the present example embodiment. FIG. 22 illustrates a second example of the substrate module according to the present example embodiment.

The substrate module according to the present example embodiment includes the mounting substrate 70. The electrolytic capacitor according to the present example embodiment may be provided on the mounting substrate 70.

The mounting substrate 70 includes the first power supply layer and the second power supply layer. For example, one of the first power supply layer and the second power supply layer may serve as the ground layer GND, and the other of the first power supply layer and the second power supply layer may serve as the DC power supply layer Vcc.

Further, the mounting substrate 70 may include a wiring line 71, a wiring line 72, and a wiring line 73 that are each provided in the form of a through-hole, for example. The wiring line 71, the wiring line 72, and the wiring line 73 may each penetrate the mounting substrate 70. For example, the wiring line 73 may be coupled to the DC power supply layer Vcc (or the ground layer GND). For example, the wiring line 71 and the wiring line 72 may be each coupled to the ground layer GND (or the DC power supply layer Vcc).

For example, in the configuration example of FIGS. 15 and 16, a part of the first coupling terminal 1 and a part of the third coupling terminal 3 may be each led out of the package 21 from the first end 61, and a part of the second coupling terminal 2 may be led out of the package 21 from the second end 62, as described above. In this case, the electrolytic capacitor may be mounted on the mounting substrate 70, as illustrated in FIG. 21. For example, the first coupling terminal 1 may be coupled to the DC power supply layer Vcc (or the ground layer GND) via the wiring line 73. For example, the second coupling terminal 2 may be coupled to the ground layer GND (or the DC power supply layer Vcc) via the wiring line 72. For example, the third coupling terminal 3 may be coupled to the ground layer GND (or the DC power supply layer Vcc) via the wiring line 71.

Such a configuration allows for formation of the closed conductor loop that includes, as a path, the wiring line 71 and the wiring line 72, with respect to the electrolytic capacitor. This makes it possible to reduce not only the parasitic inductance of the electrolytic capacitor but also the parasitic inductance (i.e., equivalent series inductance) provided by the wiring line 71, the wiring line 72, and the wiring line 73.

Further, for example, in the configuration example of FIG. 19, all of a part of the first coupling terminal 1, a part of the second coupling terminal 2, and a part of the third coupling terminal 3 may be led out of the package 21 from the first end 61, as described above. In this case, the electrolytic capacitor may be mounted on the mounting substrate 70, as illustrated in FIG. 22. In the configuration example of FIG. 22, for example, the first coupling terminal 1 may be coupled to the DC power supply layer Vcc (or the ground layer GND) via the wiring line 71. For example, the second coupling terminal 2 may be coupled to the ground layer GND (or the DC power supply layer Vcc) via the wiring line 72. For example, the third coupling terminal 3 may be coupled to the ground layer GND (or the DC power supply layer Vcc) via the wiring line 73.

Such a configuration allows for formation of the closed conductor loop that includes, as a path, the wiring line 72 and the wiring line 73, with respect to the electrolytic capacitor. This makes it possible to reduce not only the parasitic inductance of the electrolytic capacitor but also the parasitic inductance (i.e., equivalent series inductance) provided by the wiring line 71, the wiring line 72, and the wiring line 73.

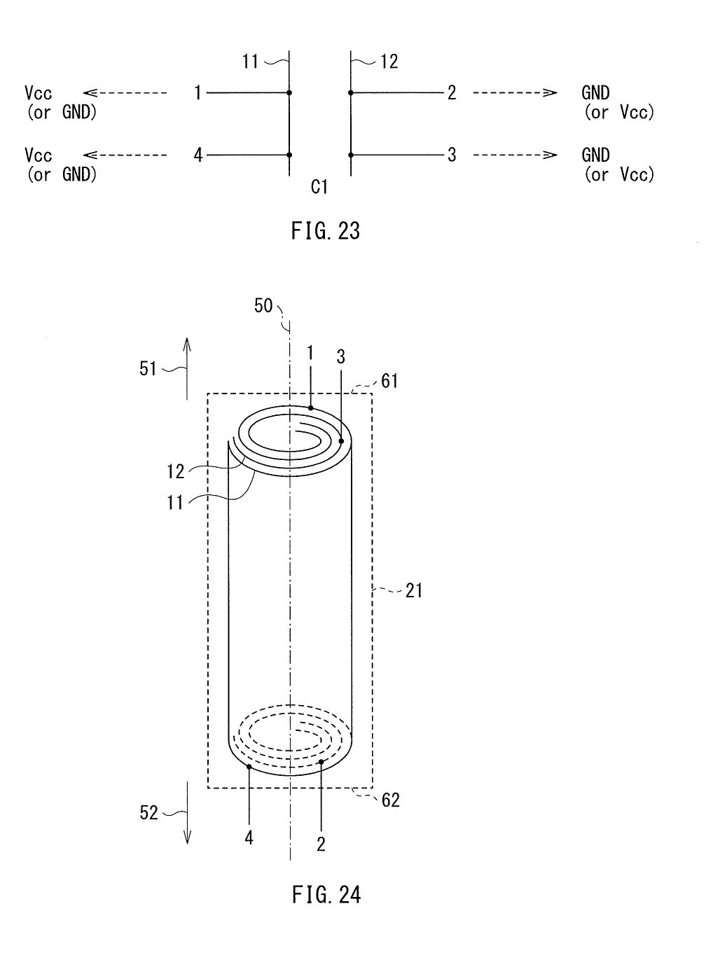

The electrolytic capacitor according to the present example embodiment may have a configuration illustrated in FIG. 23. FIG. 23 illustrates an example of a coupling mode (i.e., circuit topology) of the main part of the electrolytic capacitor according to the present example embodiment.

In the configuration example of FIG. 23, a fourth coupling terminal 4 may be further provided, in addition to the above-described configuration example of FIG. 11. The fourth coupling terminal 4 may be coupled to the first electrode 11, and a part of the fourth coupling terminal 4 may be led out of the package 21.

In this configuration example, for example, the first coupling terminal 1 and the fourth coupling terminal 4 may be each coupled to one of the ground layer GND and the DC power supply layer Vcc, while the second coupling terminal 2 and the third coupling terminal 3 may be each coupled to the other of the ground layer GND and the DC power supply layer Vcc. This allows for formation of the capacitor C1 between the DC power supply layer Vcc and the ground layer GND. Further, there may be formed a first closed conductor loop with a path of the ground layer GND (or the DC power supply layer Vcc), the second coupling terminal 2, the second electrode 12, the third coupling terminal 3, and the ground layer GND (or the DC power supply layer Vcc), for example. Furthermore, there may be formed a second closed conductor loop with a path of the DC power supply layer Vcc (or the ground layer GND), the first coupling terminal 1, the first electrode 11, the fourth coupling terminal 4, and the DC power supply layer Vcc (or the ground layer GND), for example. When the noise current In flows into the capacitor C1, a counter electromotive force is generated in the first closed conductor loop and in the second closed conductor loop in accordance with Faraday's law. The formation of the two closed conductor loops makes it possible to further reduce the parasitic inductance (i.e., equivalent series inductance) of the electrolytic capacitor, as compared with the configuration example of FIG. 11.

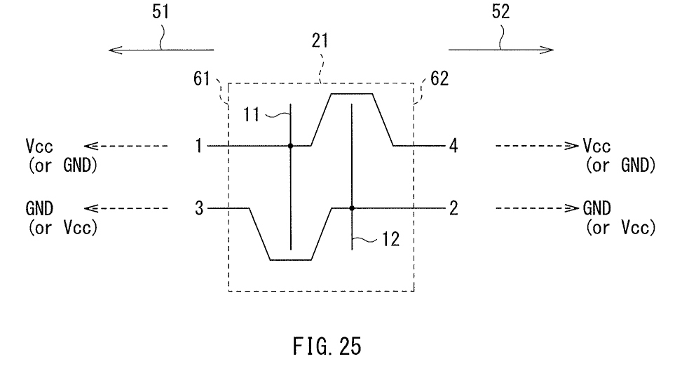

The electrolytic capacitor according to the present example embodiment may have a configuration illustrated in FIG. 24. FIG. 24 schematically illustrates another example of the electrolytic capacitor according to the present example embodiment. FIG. 25 illustrates an example of a coupling mode (i.e., circuit topology) of a main part of the electrolytic capacitor illustrated in FIG. 24.

In the configuration example of FIGS. 24 and 25, the fourth coupling terminal 4 may be further provided, in addition to the above-described configuration example of FIGS. 15 and 16. The fourth coupling terminal 4 may be coupled to the first electrode 11.

In the configuration example of FIGS. 24 and 25, a part of the first coupling terminal 1 and a part of the third coupling terminal 3 may be each led out of the package 21 from the first end 61. Further, a part of the second coupling terminal 2 and a part of the fourth coupling terminal 4 may be each led out of the package 21 from the second end 62.

For example, as illustrated in FIG. 25, a part of the first coupling terminal 1 and a part of the fourth coupling terminal 4 may be each coupleable to one of the first power supply layer and the second power supply layer. A part of the second coupling terminal 2 and a part of the third coupling terminal 3 may be each coupleable to the other of the first power supply layer and the second power supply layer.

In this configuration example, for example, the first coupling terminal 1 and the fourth coupling terminal 4 may be each coupled to one of the ground layer GND and the DC power supply layer Vcc, while the second coupling terminal 2 and the third coupling terminal 3 may be each coupled to the other of the ground layer GND and the DC power supply layer Vcc. This allows for formation of the capacitor C1 between the DC power supply layer Vcc and the ground layer GND. There may be formed a loop of the noise current In in a path of one of the ground layer GND and the DC power supply layer Vcc, the first coupling terminal 1, the capacitor C1, the second coupling terminal 2, and the other of the ground layer GND and the DC power supply layer Vcc.

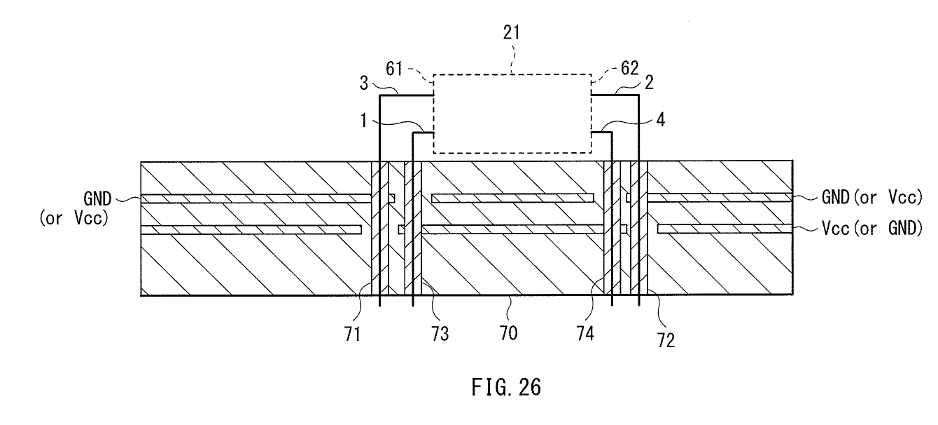

Further, there may be formed the first closed conductor loop with a path of the other of the ground layer GND and the DC power supply layer Vcc, the second coupling terminal 2, the second electrode 12, the third coupling terminal 3, and the other of the ground layer GND and the DC power supply layer Vcc. Furthermore, there may be formed the second closed conductor loop with a path of one of the ground layer GND and the DC power supply layer Vcc, the first coupling terminal 1, the first electrode 11, the fourth coupling terminal 4, and one of the ground layer GND and the DC power supply layer Vcc. When the noise current In flows into the capacitor C1, a counter electromotive force is generated in the first closed conductor loop and in the second closed conductor loop in accordance with Faraday's law. The formation of the two closed conductor loops makes it possible to further reduce the parasitic inductance (i.e., equivalent series inductance) of the electrolytic capacitor. Further, in a manner substantially similar to the configuration example of FIGS. 15 to 17, it is possible to increase overlapping areas between the loop of the noise current In and the first conductor loop and between the loop of the noise current In and the second conductor loop, thus enabling the coupling coefficient among the loops to be increased. This makes it possible to further reduce the parasitic inductance of the electrolytic capacitor. In particular, in a case where the electrolytic capacitor is mounted on the mounting substrate 70 as illustrated in FIG. 26 described later, the third coupling terminal 3 may be located close to the first coupling terminal 1, and the fourth coupling terminal 4 may be located close to the second coupling terminal 2, thus making it possible to increase the overlapping area of the two loops.

FIG. 26 illustrates an example of a substrate module mounted with the electrolytic capacitor illustrated in FIGS. 24 and 25.

In the configuration example of FIG. 26, the mounting substrate 70 includes the first power supply layer and the second power supply layer, in a manner substantially similar to the configuration example of FIG. 21. For example, one of the first power supply layer and the second power supply layer may serve as the ground layer GND, and the other of the first power supply layer and the second power supply layer may serve as the DC power supply layer Vcc.

In the configuration example of FIG. 26, the mounting substrate 70 may further include a wiring line 74 provided in the form of a through-hole, for example, in addition to the configuration example of FIG. 21. The wiring lines 71 to 74 may each penetrate the mounting substrate 70. For example, the wiring line 73 and the wiring line 74 may be each coupled to the DC power supply layer Vcc (or the ground layer GND). For example, the wiring line 71 and the wiring line 72 may be each coupled to the ground layer GND (or the DC power supply layer Vcc).

For example, in the configuration example of FIG. 25, a part of the first coupling terminal 1 and a part of the third coupling terminal 3 may be each led out of the package 21 from the first end 61, and a part of the second coupling terminal 2 and a part of the fourth coupling terminal 4 may be each led out of the package 21 from the second end 62, as described above. In this case, the electrolytic capacitor may be mounted on the mounting substrate 70, as illustrated in FIG. 26. For example, the first coupling terminal 1 may be coupled to the DC power supply layer Vcc (or the ground layer GND) via the wiring line 73. For example, the second coupling terminal 2 may be coupled to the ground layer GND (or the DC power supply layer Vcc) via the wiring line 72. For example, the third coupling terminal 3 may be coupled to the ground layer GND (or the DC power supply layer Vcc) via the wiring line 71. For example, the fourth coupling terminal 4 may be coupled to the DC power supply layer Vcc (or the ground layer GND) via the wiring line 74.

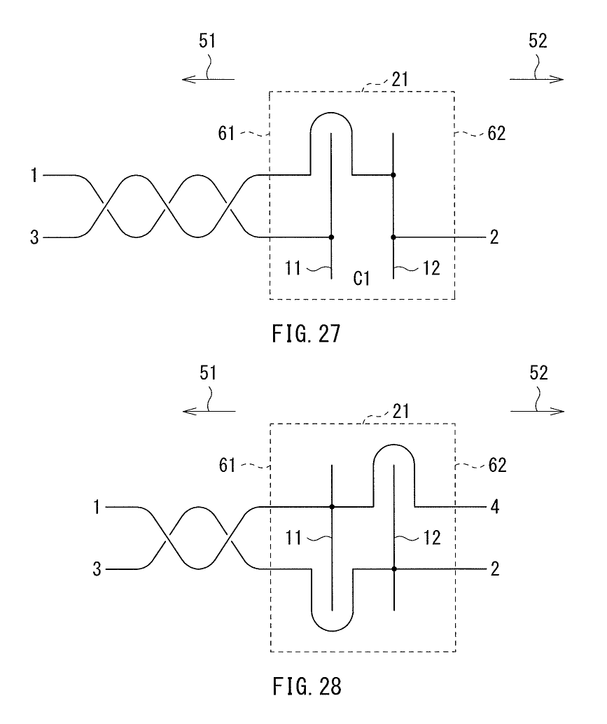

Further, the electrolytic capacitor according to the present example embodiment may have a configuration illustrated in FIG. 27 or 28. FIG. 27 illustrates a modification example of the electrolytic capacitor illustrated in FIGS. 15 and 16. FIG. 28 illustrates a modification example of the electrolytic capacitor illustrated in FIGS. 24 and 25.

In each of the configurations of FIGS. 27 and 28, the first coupling terminal 1 and the third coupling terminal 3 may be disposed partially close to each other, and may be electrically insulated from each other. As an example of the close disposition, in each of the configuration examples of FIGS. 27 and 28, the first coupling terminal 1 and the third coupling terminal 3 may be configured to be twisted together at least partially and to be electrically insulated from each other. It is to be noted that the first coupling terminal 1 and the third coupling terminal 3 may be configured to be disposed close to and substantially parallel to each other, instead of configured to be twisted together, and to be electrically insulated from each other. Further, the twisted part may be either inside or outside the package 21. In an alternative embodiment, the twisted part may be both inside and outside the package 21.

In each of the configuration examples, the first coupling terminal 1 and the third coupling terminal 3 may be disposed partially close to each other. This enables the coupling between the loop of the noise current In and the closed conductor loop to be stronger, thus making it possible to further reduce the parasitic inductance of the electrolytic capacitor.

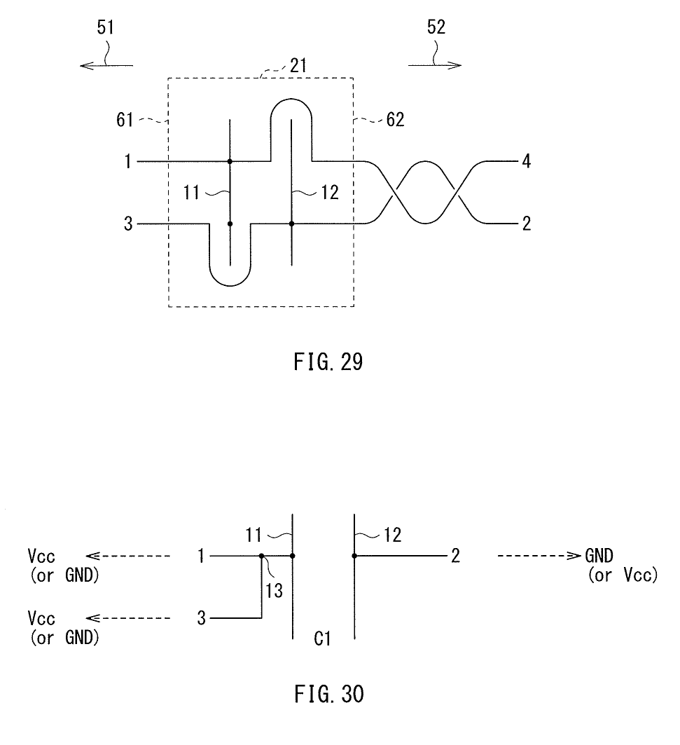

Further, the electrolytic capacitor according to the present example embodiment may have a configuration illustrated in FIG. 29. FIG. 29 illustrates a modification example of the electrolytic capacitor illustrated in FIGS. 24 and 25.

In the configuration example of FIG. 29, the second coupling terminal 2 and the fourth coupling terminal 4 may be disposed partially close to each other, and may be electrically insulated from each other. As an example of the close disposition, in the configuration example of FIG. 29, the second coupling terminal 2 and the fourth coupling terminal 4 may be configured to be twisted together at least partially and to be electrically insulated from each other. It is to be noted that the second coupling terminal 2 and the fourth coupling terminal 4 may be configured to be disposed close to and substantially parallel to each other, instead of configured to be twisted together, and to be electrically insulated from each other. Further, the twisted part may be either inside or outside the package 21. In an alternative embodiment, the twisted part may be both inside and outside the package 21.

In this configuration example, the second coupling terminal 2 and the fourth coupling terminal 4 may be disposed partially close to each other. This enables the coupling between the loop of the noise current In and the closed conductor loop to be stronger, thus making it possible to further reduce the parasitic inductance of the electrolytic capacitor.

Further, in the configuration example of FIG. 29, for example, the first coupling terminal 1 and the third coupling terminal 3 may be configured to be twisted together at least partially and to be electrically insulated from each other, similarly to the configuration example of FIG. 28, although this configuration is not illustrated.

### 2. Second Example Embodiment

Description is given next of the electrolytic capacitor and the substrate module according to a second example embodiment of the disclosure. It is to be noted that, in the following, parts that are substantially the same as the components of the capacitor and the substrate module according to the foregoing comparative example or as the components of the electrolytic capacitor and the substrate module according to the foregoing first example embodiment are denoted with the same reference numerals, and descriptions thereof are omitted where appropriate.

FIG. 30 illustrates an example of a coupling mode (i.e., circuit topology) of a main part of the electrolytic capacitor according to the second example embodiment.

The electrolytic capacitor according to the present example embodiment further includes the third coupling terminal 3 in addition to the components of the electrolytic capacitor according to the comparative example.

The third coupling terminal 3 is coupled to an intermediate part 13 of the first coupling terminal 1. The third coupling terminal 3 may extend from the intermediate part 13 of the first coupling terminal 1, in a direction that is different from an extending direction of the first coupling terminal 1. A part of the third coupling terminal 3 may be then led out of the package 21.

It is to be noted that the intermediate part 13 may be at any position of the first coupling terminal 1 other than both ends thereof, i.e., any position of the first coupling terminal 1 between the position at which the first coupling terminal 1 and the first electrode 11 are coupled to each other and a part of the first coupling terminal 1 led out of the package 21.

In the configuration example of FIG. 30, for example, the first coupling terminal 1 may be coupled to one of the ground layer GND and the DC power supply layer Vcc, and the second coupling terminal 2 may be coupled to the other of the ground layer GND and the DC power supply layer Vcc, thereby forming the capacitor C1 between the DC power supply layer Vcc and the ground layer GND.

In the configuration example of FIG. 30, the third coupling terminal 3 may extend in the direction that is different from the extending direction of the first coupling terminal 1, and the first coupling terminal 1 and the third coupling terminal 3 may be each coupled to one of the ground layer GND and the DC power supply layer Vcc. This allows for formation of a closed conductor loop with a path of one of the ground layer GND and the DC power supply layer Vcc, the first coupling terminal 1, the third coupling terminal 3, and one of the ground layer GND and the DC power supply layer Vcc. When the noise current In flows into the capacitor C1, a counter electromotive force is generated in the closed conductor loop in accordance with Faraday's law. This makes it possible to reduce the parasitic inductance of the electrolytic capacitor.

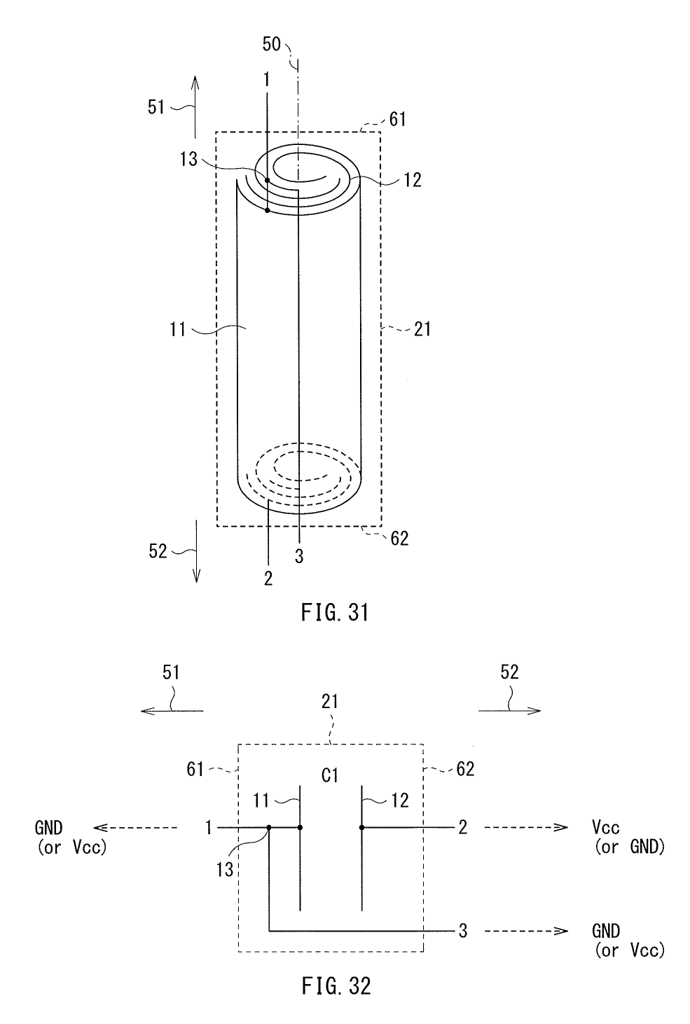

Further, the electrolytic capacitor according to the present example embodiment may have a configuration illustrated in FIG. 31. FIG. 31 schematically illustrates an example of the electrolytic capacitor according to the present example embodiment. FIG. 32 illustrates an example of a coupling mode (i.e., circuit topology) of a main part of the electrolytic capacitor illustrated in FIG. 31.

In the configuration example of FIGS. 31 and 32, a part of the first coupling terminal 1 may be led out of the package 21 from the first end 61. Further, a part of the second coupling terminal 2 and a part of the third coupling terminal 3 may be each led out of the package 21 from the second end 62.

In the configuration example of FIGS. 31 and 32, the first coupling terminal 1 may be coupled to one of the ground layer GND and the DC power supply layer Vcc from the first end 61, and the second coupling terminal 2 may be coupled to the other of the ground layer GND and the DC power supply layer Vcc from the second end 62, thereby forming the capacitor C1 between the DC power supply layer Vcc and the ground layer GND. The third coupling terminal 3 may be coupled to the other of the ground layer GND and the DC power supply layer Vcc from the second end 62. This increases overlapping area between the closed conductor loop, that includes the first coupling terminal 1 and the third coupling terminal 3, and the loop (i.e., a path of the noise current In) in which the capacitor C1 is formed, in a manner substantially similar to the configuration example of FIGS. 15 to 17. The increased overlapping area enables the coupling between the loops to be enhanced. This makes it possible to further reduce the parasitic inductance of the electrolytic capacitor.

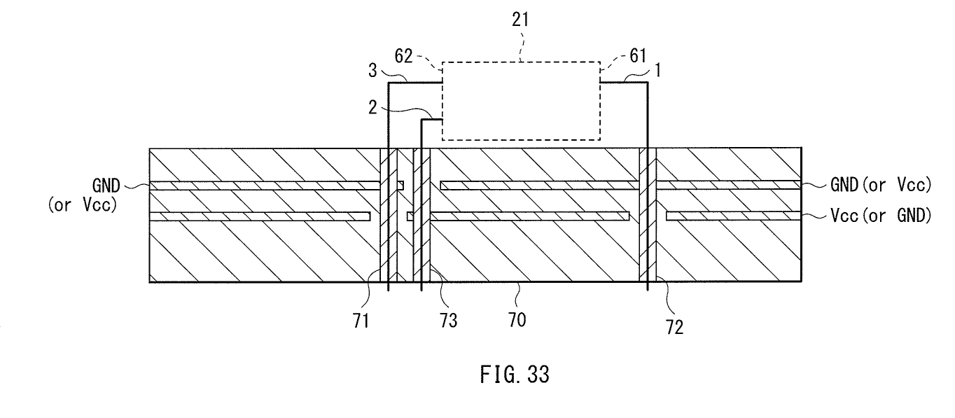

The electrolytic capacitor according to the configuration example of FIGS. 31 to 32 may be mounted on the mounting substrate 70 in manner substantially similar to the configuration example of FIG. 21, thereby forming the substrate module. In a specific but non-limiting example, the electrolytic capacitor mounted on the mounting substrate 70 may form the substrate module, for example, as illustrated in FIG. 33. For example, the first coupling terminal 1 may be coupled to the ground layer GND (or the DC power supply layer Vcc) via the wiring line 72. For example, the second coupling terminal 2 may be coupled to the DC power supply layer Vcc (or the ground layer GND) via the wiring line 73. For example, the third coupling terminal 3 may be coupled to the ground layer GND (or the DC power supply layer Vcc) via the wiring line 71. Such a configuration allows for formation of a closed conductor loop that includes, as a path, the wiring line 71 and the wiring line 72, with respect to the electrolytic capacitor. This makes it possible to reduce not only the parasitic inductance of the electrolytic capacitor but also the parasitic inductance (i.e., equivalent series inductance) provided by the wiring line 71, the wiring line 72, and the wiring line 73.

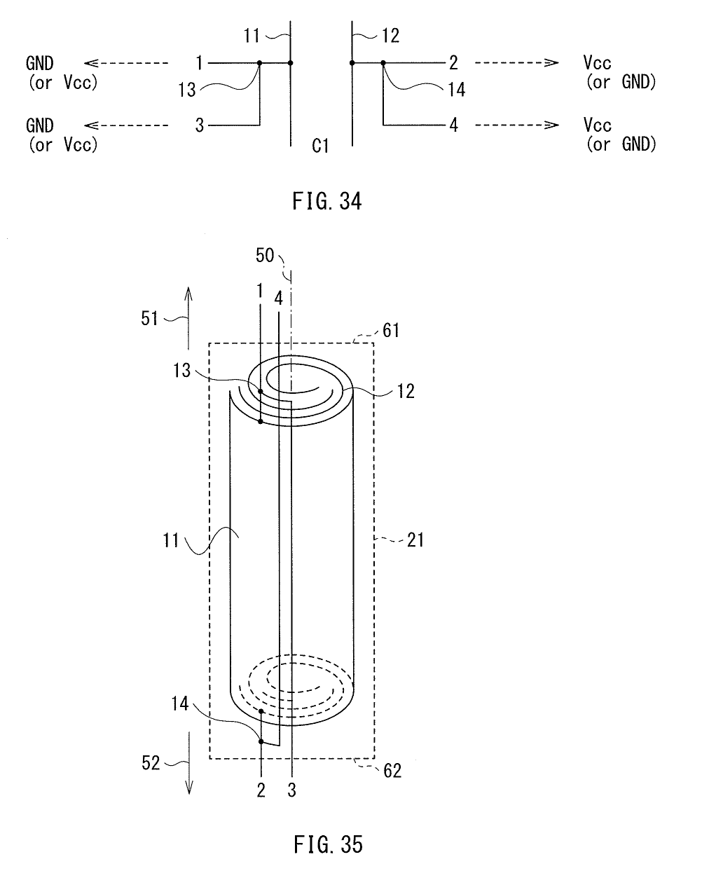

Further, the electrolytic capacitor according to the present example embodiment may have a configuration illustrated in FIG. 34. FIG. 34 illustrates an example of a coupling mode (i.e., circuit topology) of a main part of the electrolytic capacitor according to the present example embodiment.

In the configuration example of FIG. 34, the fourth coupling terminal 4 may be further provided, in addition to the above-described configuration example of FIG. 30. The fourth coupling terminal 4 may be coupled to an intermediate part 14 of the second coupling terminal 2. The fourth coupling terminal 4 may extend from the intermediate part 14 of the second coupling terminal 2, in a direction that is different from an extending direction of the second coupling terminal 2. A part of the fourth coupling terminal 4 may be then led out of the package 21.

It is to be noted that the intermediate part 14 may be at any position of the second coupling terminal 2 other than both ends thereof, i.e., any position of the second coupling terminal 2 between the position at which the second coupling terminal 2 and the second electrode 12 are coupled to each other and a part of the second coupling terminal 2 led out of the package 21.

In this configuration example, for example, the first coupling terminal 1 and the third coupling terminal 3 may be each coupled to one of the ground layer GND and the DC power supply layer Vcc, and the second coupling terminal 2 and the fourth coupling terminal 4 may be each coupled to the other of the ground layer GND and the DC power supply layer Vcc. This allows for formation of the capacitor C1 between the DC power supply layer Vcc and the ground layer GND. Further, the third coupling terminal 3 extending in the direction that is different from the extending direction of the first coupling terminal 1 allows for formation of the first conductor loop. The first conductor loop has a path of one of the ground layer GND and the DC power supply layer Vcc, the first coupling terminal 1, the third coupling terminal 3, and one of the ground layer GND and the DC power supply layer Vcc. Furthermore, the fourth coupling terminal 4 extending in the direction that is different from the extending direction of the second coupling terminal 2 allows for formation of the second conductor loop. The second conductor loop has a path of the other of the ground layer GND and the DC power supply layer Vcc, the second coupling terminal 2, the fourth coupling terminal 4, and the other of the ground layer GND and the DC power supply layer Vcc. When the noise current In flows into the capacitor C1, a counter electromotive force is generated in the first closed conductor loop and in the second closed conductor loop in accordance with Faraday's law. The formation of the two closed conductor loops makes it possible to further reduce the parasitic inductance (i.e., equivalent series inductance) of the electrolytic capacitor, as compared with the configuration example of FIG. 30.

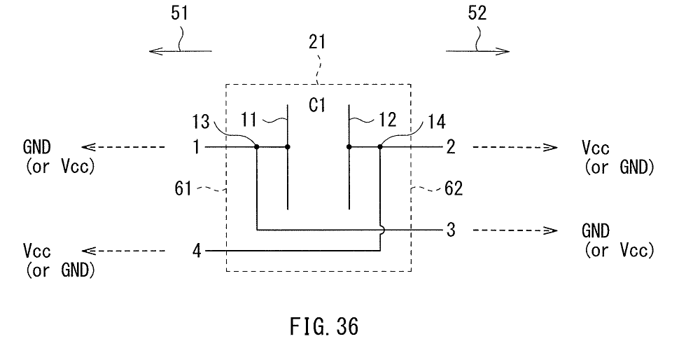

Further, the electrolytic capacitor according to the present example embodiment may have a configuration illustrated in FIG. 35. FIG. 35 schematically illustrates another example of the electrolytic capacitor according to the present example embodiment. FIG. 36 illustrates an example of a coupling mode (i.e., circuit topology) of a main part of the electrolytic capacitor illustrated in FIG. 35.

In the configuration example of FIGS. 35 and 36, the fourth coupling terminal 4 may be further provided, in addition to the above-described configuration example of FIGS. 31 and 32. The fourth coupling terminal 4 may be coupled to the intermediate part 14 of the second coupling terminal 2. The fourth coupling terminal 4 may extend from the intermediate part 14 of the second coupling terminal 2, in a direction that is different from the extending direction of the second coupling terminal 2. A part of the fourth coupling terminal 4 may be then led out of the package 21.

In the configuration example of FIGS. 35 and 36, a part of the first coupling terminal 1 and a part of the fourth coupling terminal 4 may be each led out of the package 21 from the first end 61. Further, a part of the second coupling terminal 2 and a part of the third coupling terminal 3 may be each led out of the package 21 from the second end 62.

In the configuration example of FIGS. 35 and 36, the first coupling terminal 1 and the third coupling terminal 3 may be each coupled to one of the DC power supply layer Vcc and the ground layer GND. This allows for formation of the first closed conductor loop with a path of one of the DC power supply layer Vcc and the ground layer GND, the first coupling terminal 1, the third coupling terminal 3, and one of the DC power supply layer Vcc and the ground layer GND. Further, the second coupling terminal 2 and the fourth coupling terminal 4 may be each coupled to the other of the DC power supply layer Vcc and the ground layer GND. This allows for formation of the second closed conductor loop with a path of the other of the DC power supply layer Vcc and the ground layer GND, the second coupling terminal 2, the fourth coupling terminal 4, and the other of the DC power supply layer Vcc and the ground layer GND. This increases overlapping areas between the loop of the noise current In and the first conductor loop and between the loop of the noise current In and the second conductor loop, in a manner substantially similar to the configuration example of FIGS. 24 and 25, thus enabling the coupling among the loops to be enhanced. This makes it possible to further reduce the parasitic inductance of the electrolytic capacitor.

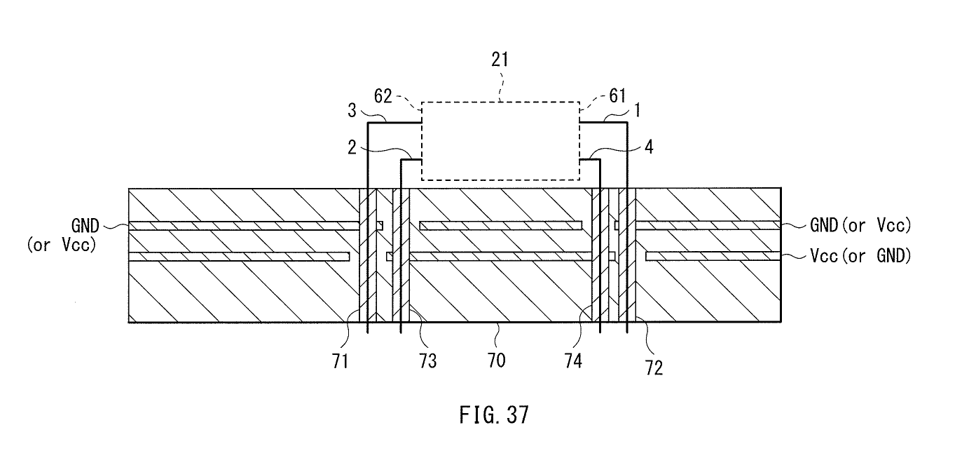

The electrolytic capacitor according to the configuration example of FIGS. 35 to 36 may be mounted on the mounting substrate 70 in manner substantially similar to the configuration example of FIG. 26, thereby forming the substrate module. In a specific but non-limiting example, the electrolytic capacitor mounted on the mounting substrate 70 may form the substrate module, for example, as illustrated in FIG. 37. For example, the first coupling terminal 1 may be coupled to the ground layer GND (or the DC power supply layer Vcc) via the wiring line 72. For example, the second coupling terminal 2 may be coupled to the DC power supply layer Vcc (or the ground layer GND) via the wiring line 73. For example, the third coupling terminal 3 may be coupled to the ground layer GND (or the DC power supply layer Vcc) via the wiring line 71. For example, the fourth coupling terminal 4 may be coupled to the DC power supply layer Vcc (or the ground layer GND) via the wiring line 74. Such a configuration allows for formation of a closed conductor loop that includes, as a path, the wiring line 71 and the wiring line 72, with respect to the electrolytic capacitor. Such a configuration also allows for a closed conductor loop that includes, as a path, the wiring line 73 and the wiring line 74, with respect to the electrolytic capacitor. This makes it possible to reduce not only the parasitic inductance of the electrolytic capacitor but also the parasitic inductance (i.e., equivalent series inductance) provided by the wiring line 71, the wiring line 72, and the wiring line 73.

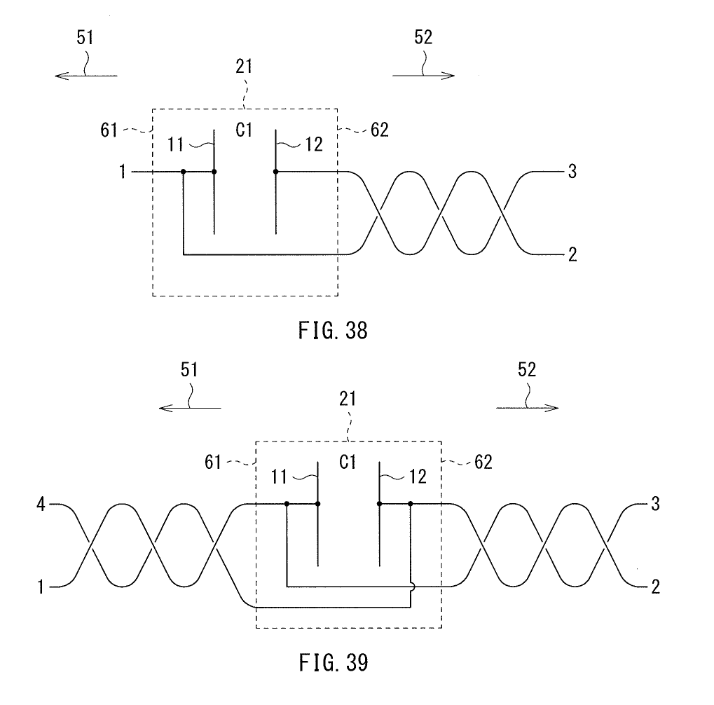

Further, the electrolytic capacitor according to the present example embodiment may have a configuration illustrated in FIG. 38. FIG. 38 illustrates a modification example of the electrolytic capacitor illustrated in FIGS. 31 and 32.

In the configuration example of FIG. 38, the second coupling terminal 2 and the third coupling terminal 3 may be disposed partially close to each other, and may be electrically insulated from each other. As an example of the close disposition, in the configuration example of FIG. 38, the second coupling terminal 2 and the third coupling terminal 3 may be configured to be twisted together at least partially and to be electrically insulated from each other. It is to be noted that the second coupling terminal 2 and the third coupling terminal 3 may be configured to be disposed close to and substantially parallel to each other, instead of configured to be twisted together, and to be electrically insulated from each other. Further, the twisted part may be either inside or outside the package 21. In an alternative embodiment, the twisted part may be both inside and outside the package 21.

In this configuration example, the second coupling terminal 2 and the third coupling terminal 3 may be disposed partially close to each other. This enables the coupling between the loop of the noise current In and the closed conductor loop to be stronger, thus making it possible to further reduce the parasitic inductance of the electrolytic capacitor.

Further, the electrolytic capacitor according to the present example embodiment may have a configuration illustrated in FIG. 39. FIG. 39 illustrates a modification example of the electrolytic capacitor illustrated in FIGS. 35 and 36.

In the configuration example of FIG. 39, the second coupling terminal 2 and the third coupling terminal 3 may be disposed partially close to each other, and may be electrically insulated from each other. As an example of the close disposition, in the configuration example of FIG. 39, the second coupling terminal 2 and the third coupling terminal 3 may be configured to be twisted together at least partially and to be electrically insulated from each other. It is to be noted that the second coupling terminal 2 and the third coupling terminal 3 may be configured to be disposed close to and substantially parallel to each other, instead of configured to be twisted together, and to be electrically insulated from each other. Likewise, the first coupling terminal 1 and the fourth coupling terminal 4 may be disposed partially close to each other, and may be electrically insulated from each other. As an example of the close disposition, in the configuration example of FIG. 39, the first coupling terminal 1 and the fourth coupling terminal 4 may be configured to be twisted together at least partially and to be electrically insulated from each other. It is to be noted that the first coupling terminal 1 and the fourth coupling terminal 4 may be configured to be disposed close to and substantially parallel to each other, instead of configured to be twisted together, and to be electrically insulated from each other. Further, the twisted part may be either inside or outside the package 21. In an alternative embodiment, the twisted part may be both inside and outside the package 21. Furthermore, in the configuration example of FIG. 39, a first combination of the first coupling terminal 1 and the fourth coupling terminal 4 and a second combination of the second coupling terminal 2 and the third coupling terminal 3 are both configured to be twisted together. In an alternative example, however, only one of the two combinations may be configured to be twisted together.

In this configuration example, one or both of the first combination of the first coupling terminal 1 and the fourth coupling terminal 4 and the second combination of the second coupling terminal 2 and the third coupling terminal 3 may be disposed partially close to each other. This enables the coupling between the loop of the noise current In and the closed conductor loop to be stronger, thus making it possible to further reduce the parasitic inductance of the electrolytic capacitor.

Other configurations, operations, and effects are substantially similar to those of the electrolytic capacitor and the substrate module according to the foregoing first example embodiment.

### 3. Third Example Embodiment

Description is given next of the electrolytic capacitor and the substrate module according to a third example embodiment of the disclosure. It is to be noted that, in the following, parts that are substantially the same as the components of the capacitor and the substrate module according to the foregoing comparative example or as the components of the electrolytic capacitor and the substrate module according to the foregoing first or second example embodiment are denoted with the same reference numerals, and descriptions thereof are omitted where appropriate.

FIG. 40 illustrates an example of a coupling mode (i.e., circuit topology) of a main part of the electrolytic capacitor according to the third example embodiment. FIG. 41 illustrates an example of the closed conductor loop 30 formed by the electrolytic capacitor illustrated in FIG. 40.

The electrolytic capacitor according to the present example embodiment further includes the third coupling terminal 3 and the fourth coupling terminal 4, in addition to the components of the electrolytic capacitor according to the comparative example.

The third coupling terminal 3 and the fourth coupling terminal 4 may be coupled to each other at a position different from those in the first electrode 11 and the second electrode 12 inside the package 21. A part of the third coupling terminal 3 and a part of the fourth coupling terminal 4 may be each led out of the package 21.

In the configuration example of FIG. 40, for example, the first coupling terminal 1 may be coupled to one of the ground layer GND and the DC power supply layer Vcc, and the second coupling terminal 2 may be coupled to the other of the ground layer GND and the DC power supply layer Vcc, thereby forming the capacitor C1 between the DC power supply layer Vcc and the ground layer GND.

In the configuration example of FIG. 40, a part of the third coupling terminal 3 and a part of the fourth coupling terminal 4 may be each coupled to the same power supply layer of one of the ground layer GND and the DC power supply layer Vcc. This allows for formation of the closed conductor loop 30 of the third coupling terminal 3, the fourth coupling terminal 4, and the power supply layer of one of the ground layer GND and the DC power supply layer Vcc, as illustrated in FIG. 41. When the noise current In flows into the capacitor C1, a counter electromotive force is generated in the closed conductor loop 30 in accordance with Faraday's law. This makes it possible to reduce the parasitic inductance of the electrolytic capacitor.

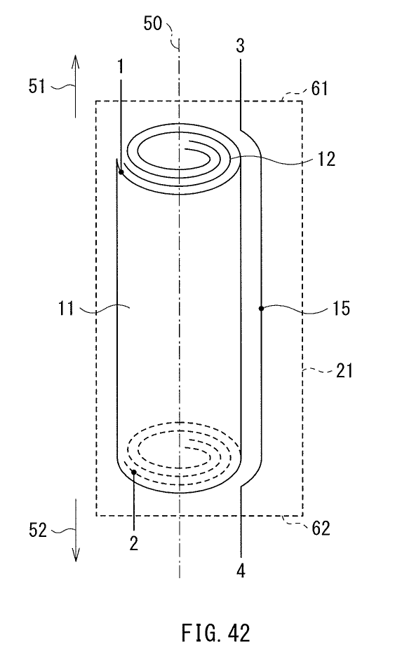

Further, the electrolytic capacitor according to the present example embodiment may have a configuration illustrated in FIG. 42. FIG. 42 schematically illustrates an example of the electrolytic capacitor according to the present example embodiment.

In the configuration example of FIG. 42, a part of the first coupling terminal 1 and a part of the third coupling terminal 3 may be each led out of the package 21 from the first end 61. Further, a part of the second coupling terminal 2 and a part of the fourth coupling terminal 4 may be each led out of the package 21 from the second end 62.

In this configuration example, there is large overlapping area between two loops. One of the two loops may be a loop (i.e., a path of the noise current In) that includes the first coupling terminal 1 led from the first end 61, the first electrode 11, the second electrode 12, and the second coupling terminal 2 led from the second end 62. The other of the two loops may be a closed conductor loop that includes the third coupling terminal 3 led from the first end 61 and the fourth coupling terminal 4 led from the second end 62. The large overlapping area between the loops makes it possible to further reduce the parasitic inductance of the electrolytic capacitor. For example, in a case where the electrolytic capacitor is mounted on the mounting substrate 70 in a manner substantially similar to the configuration example of FIG. 26, the third coupling terminal 3 may be located close to the first coupling terminal 1, and the fourth coupling terminal 4 may be located close to the second coupling terminal 2, thus making it possible to increase the overlapping area of the two loops.

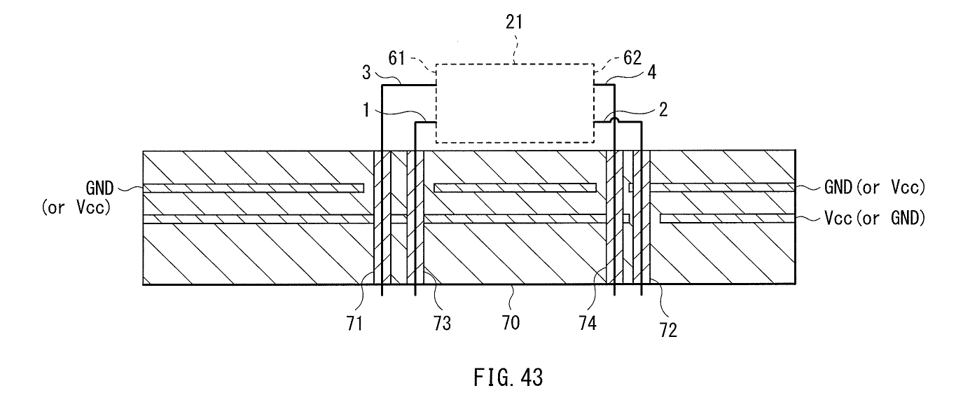

The electrolytic capacitor according to the configuration example of FIGS. 40 and 42 may be mounted on the mounting substrate 70 in a manner substantially similar to the configuration example of FIG. 26, thereby forming the substrate module. In a specific but non-limiting example, the electrolytic capacitor mounted on the mounting substrate 70 may form the substrate module, for example, as illustrated in FIG. 43. For example, the first coupling terminal 1 may be coupled to the DC power supply layer Vcc (or the ground layer GND) via the wiring line 73. For example, the second coupling terminal 2 may be coupled to the ground layer GND (or the DC power supply layer Vcc) via the wiring line 72. For example, the third coupling terminal 3 may be coupled to the DC power supply layer Vcc (or the ground layer GND) via the wiring line 71. For example, the fourth coupling terminal 4 may be coupled to the DC power supply layer Vcc (or the ground layer GND) via the wiring line 74. Such a configuration allows for formation of a closed conductor loop that includes, as a path, the third coupling terminal 3, the fourth coupling terminal 4, the wiring line 71, and the wiring line 74. This makes it possible to reduce not only the parasitic inductance of the electrolytic capacitor but also the parasitic inductance (i.e., equivalent series inductance) provided by the wiring line 71, the wiring line 72, the wiring line 73, and the wiring line 74.

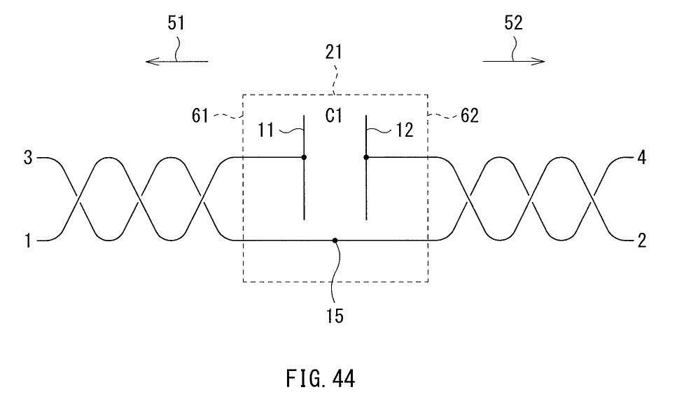

Further, the electrolytic capacitor according to the present example embodiment may have a configuration illustrated in FIG. 44. FIG. 44 illustrates a modification example of the electrolytic capacitor illustrated in FIGS. 40 and 42.

In the configuration example of FIG. 44, the first coupling terminal 1 and the third coupling terminal 3 may be disposed partially close to each other, and may be electrically insulated from each other. As an example of the close disposition, in the configuration example of FIG. 44, the first coupling terminal 1 and the third coupling terminal 3 may be configured to be twisted together at least partially and to be electrically insulated from each other. It is to be noted that the first coupling terminal 1 and the third coupling terminal 3 may be configured to be disposed close to and substantially parallel to each other, instead of configured to be twisted together, and to be electrically insulated from each other. Likewise, the second coupling terminal 2 and the fourth coupling terminal 4 may be disposed partially close to each other, and may be electrically insulated from each other. As an example of the close disposition, in the configuration example of FIG. 44, the second coupling terminal 2 and the fourth coupling terminal 4 may be configured to be twisted together at least partially and to be electrically insulated from each other. It is to be noted that the second coupling terminal 2 and the fourth coupling terminal 4 may be configured to be disposed close to and substantially parallel to each other, instead of configured to be twisted together, and to be electrically insulated from each other. Further, the twisted part may be either inside or outside the package 21. In an alternative embodiment, the twisted part may be both inside and outside the package 21. Furthermore, in the configuration example of FIG. 44, a first combination of the first coupling terminal 1 and the third coupling terminal 3 and a second combination of the second coupling terminal 2 and the fourth coupling terminal 4 are both configured to be twisted together. In an alternative example, however, only one of the two combinations may be configured to be twisted together.

In this configuration example, one or both of the first combination of the first coupling terminal 1 and the third coupling terminal 3 and the second combination of the second coupling terminal 2 and the fourth coupling terminal 4 may be disposed partially close to each other. This enables the coupling between the loop of the noise current In and the closed conductor loop to be stronger, thus making it possible to further reduce the parasitic inductance of the electrolytic capacitor.

Other configurations, operations, and effects are substantially similar to those of the electrolytic capacitor and the substrate module according to the foregoing first or second example embodiment.

### 4. Other Example Embodiments

The techniques according to the present disclosure are not limited to the foregoing example embodiments, and may be modified in a variety of ways.

For example, the substrate module mounted with any of the electrolytic capacitors according to the foregoing respective example embodiments may be used as a substrate of a power supply module such as a DC-DC converter. In an alternative embodiment, the substrate module may be used as a substrate for a set of functions of a unit such as a smartphone, a personal computer (PC), and a notebook PC. In another alternative embodiment, the substrate module may be used as a substrate of a device such as a graphic board, a microcomputer board, a memory board, and a PCI Express board.

Moreover, the disclosure encompasses any possible combination of some or all of the various embodiments and the modification examples described herein and incorporated herein.

It is possible to achieve at least the following configurations from the above-described example embodiments of the disclosure.

(1) A capacitor including:
a package;
a first electrode and a second electrode that face each other and spaced apart from each other to avoid mutual contact, the first electrode and the second electrode being each wound in an eddy shape around a rotational axis inside the package;
a first coupling terminal coupled to the first electrode and having a part that is led out of the package;
a second coupling terminal coupled to the second electrode and having a part that is led out of the package; and
a third coupling terminal coupled to the second electrode and having a part that is led out of the package.
   (2) The capacitor according to (1), in which
the package includes
   a first end located in a first direction of the rotational axis as viewed from an inside of the package, and
   a second end located in a second direction of the rotational axis as viewed from the inside of the package, the second direction being different from the first direction,
the part of the first coupling terminal and the part of the third coupling terminal are each led out of the package from the first end, and
the part of the second coupling terminal is led out of the package from the second end.
   (3) The capacitor according to (1), in which
the package includes
   a first end located in a first direction of the rotational axis as viewed from an inside of the package, and
   a second end located in a second direction of the rotational axis as viewed from the inside of the package, the second direction being different from the first direction,
all of the respective parts of the first coupling terminal, the second coupling terminal, and the third coupling terminal are led out of the package from the first end, and
θ ranges from 0° to 90°,
where
the package is projected onto a plane that is perpendicular to the rotational axis from an infinite distance of the rotational axis,
a line segment that connects the rotational axis to a position at which the first coupling terminal is coupled to the first electrode is a first line segment,
a line segment that connects the rotational axis to a position at which the third coupling terminal is coupled to the second electrode is a second line segment, and
θ denotes a minor angle formed between the first line segment and the second line segment.
   (4) The capacitor according to (3), in which, the third coupling terminal is coupled to a position of the second electrode that is adjacent, within the range of the angle θ, to a coupling position of the first electrode to the first coupling terminal, where the package is projected onto the plane that is perpendicular to the rotational axis from the infinite distance of the rotational axis.
   (5) The capacitor according to (1), further including a fourth coupling terminal coupled to the first electrode and having a part that is led out of the package.
   (6) The capacitor according to (5), in which
the package includes
   a first end located in a first direction of the rotational axis as viewed from an inside of the package, and
   a second end located in a second direction of the rotational axis as viewed from the inside of the package, the second direction being different from the first direction,
the part of the first coupling terminal and the part of the third coupling terminal are each led out of the package from the first end, and
the part of the second coupling terminal and the part of the fourth coupling terminal are each led out of the package from the second end.
   (7) The capacitor according to any one of (1) to (6), in which the first coupling terminal and the third coupling terminal are twisted together partially and electrically insulated from each other.
   (8) The capacitor according to (5) or (6), in which the second coupling terminal and the fourth coupling terminal are twisted together partially and electrically insulated from each other.
   (9) A substrate module including:
the capacitor according to any one of (1) to (8); and
a mounting substrate that includes a first power supply layer and a second power supply layer.
   (10) The substrate module according to (9), in which
the part of the first coupling terminal is coupled to one of the first power supply layer and the second power supply layer, and
the part of the second coupling terminal and the part of the third coupling terminal are each coupled to the other of the first power supply layer and the second power supply layer.
   (11) A capacitor including:
a package;
a first electrode and a second electrode that face each other and spaced apart from each other to avoid mutual contact, the first electrode and the second electrode being each wound in an eddy shape around a rotational axis inside the package;
a first coupling terminal coupled to the first electrode and having a part that is led out of the package;
a second coupling terminal coupled to the second electrode and having a part that is led out of the package; and
a third coupling terminal that is coupled to an intermediate part of the first coupling terminal, and extends from the intermediate part of the first coupling terminal in a direction that is different from an extending direction of the first coupling terminal, the third coupling terminal having a part that is led out of the package after extending from the intermediate part.
   (12) The capacitor according to (11), in which
the package includes
   a first end located in a first direction of the rotational axis as viewed from an inside of the package, and
   a second end located in a second direction of the rotational axis as viewed from the inside of the package, the second direction being different from the first direction,
the part of the first coupling terminal is led out of the package from the first end, and
the part of the second coupling terminal and the part of the third coupling terminal are each led out of the package from the second end.
   (13) The capacitor according to (11), further including a fourth coupling terminal that is coupled to an intermediate part of the second coupling terminal, and extends from the intermediate part of the second coupling terminal in a direction that is different from an extending direction of the second coupling terminal, the fourth coupling terminal having a part that is led out of the package after extending from the intermediate part.
   (14) The capacitor according to (13), in which
the package includes
   a first end located in a first direction of the rotational axis as viewed from an inside of the package, and
   a second end located in a second direction of the rotational axis as viewed from the inside of the package, the second direction being different from the first direction,
the part of the first coupling terminal and the part of the fourth coupling terminal are each led out of the package from the first end, and
the part of the second coupling terminal and the part of the third coupling terminal are each led out of the package from the second end.
   (15) The capacitor according to (12), in which the second coupling terminal and the third coupling terminal are twisted together partially and electrically insulated from each other.
   (16) The capacitor according to (14), in which the first coupling terminal and the fourth coupling terminal are twisted together partially and electrically insulated from each other.
   (17) A substrate module including:
the capacitor according to any one of (11) to (16); and
a mounting substrate that includes a first power supply layer and a second power supply layer.
   (18) The substrate module according to (17), in which
the part of the first coupling terminal and the part of the third coupling terminal are each coupled to one of the first power supply layer and the second power supply layer, and
the part of the second coupling terminal is coupled to the other of the first power supply layer and the second power supply layer.
   (19) A capacitor including:
a package;
a first electrode and a second electrode that face each other and spaced apart from each other to avoid mutual contact, the first electrode and the second electrode being each wound in an eddy shape around a rotational axis inside the package;
a first coupling terminal coupled to the first electrode and having a part that is led out of the package;
a second coupling terminal coupled to the second electrode and having a part that is led out of the package; and
a third coupling terminal and a fourth coupling terminal that are coupled to each other inside the package, with a part of the third coupling terminal and a part of the fourth coupling terminal being each led out of the package.
   (20) The capacitor according to (19), in which
the package includes
   a first end located in a first direction of the rotational axis as viewed from an inside of the package, and
   a second end located in a second direction of the rotational axis as viewed from the inside of the package, the second direction being different from the first direction,
the part of the first coupling terminal and the part of the third coupling terminal are each led out of the package from the first end, and
the part of the second coupling terminal and the part of the fourth coupling terminal are each led out of the package from the second end.
   (21) The capacitor according to (20), in which coupling terminals of one or both of a first combination and a second combination are twisted together partially and electrically insulated from each other, the first combination including the first coupling terminal and the third coupling terminal, the second combination including the second coupling terminal and the fourth coupling terminal.
   (22) A substrate module including:
the capacitor according to any one of (19) to (21); and
a mounting substrate that includes a first power supply layer and a second power supply layer.
   (23) The substrate module according to (22), in which
the part of the first coupling terminal is coupled to one of the first power supply layer and the second power supply layer,
the part of the second coupling terminal is coupled to the other of the first power supply layer and the second power supply layer, and
the part of the third coupling terminal and the part of the fourth coupling terminal are each coupled to a same power supply layer of the first power supply layer and the second power supply layer.

According to the capacitor and the substrate module of the respective embodiments of the disclosure, it is possible to reduce the equivalent series inductance.

Although the disclosure has been described in terms of exemplary embodiments, it is not limited thereto. It should be appreciated that variations may be made in the described embodiments by persons skilled in the art without departing from the scope of the disclosure as defined by the following claims. The limitations in the claims are to be interpreted broadly based on the language employed in the claims and not limited to examples described in this specification or during the prosecution of the application, and the examples are to be construed as non-exclusive. For example, in this disclosure, the term “preferably”, “preferred” or the like is non-exclusive and means “preferably”, but not limited to. The use of the terms first, second, etc. do not denote any order or importance, but rather the terms first, second, etc. are used to distinguish one element from another. The term “substantially” and its variations are defined as being largely but not necessarily wholly what is specified as understood by one of ordinary skill in the art. The term “about” as used herein can allow for a degree of variability in a value or range. Moreover, no element or component in this disclosure is intended to be dedicated to the public regardless of whether the element or component is explicitly recited in the following claims.

What is claimed is:

1. A capacitor comprising:
a package;
a first electrode and a second electrode that face each other and spaced apart from each other to avoid mutual contact, the first electrode and the second electrode being each wound in an eddy shape around a rotational axis inside the package;
a first coupling terminal coupled to the first electrode and having a part that is led out of the package;
a second coupling terminal coupled to the second electrode and having a part that is led out of the package; and
a third coupling terminal coupled to the second electrode and having a part that is led out of the package.

2. The capacitor according to claim 1, wherein
the package includes
a first end located in a first direction of the rotational axis as viewed from an inside of the package, and
a second end located in a second direction of the rotational axis as viewed from the inside of the package, the second direction being different from the first direction,
the part of the first coupling terminal and the part of the third coupling terminal are each led out of the package from the first end, and
the part of the second coupling terminal is led out of the package from the second end.

3. The capacitor according to claim 1, wherein
the package includes
a first end located in a first direction of the rotational axis as viewed from an inside of the package, and
a second end located in a second direction of the rotational axis as viewed from the inside of the package, the second direction being different from the first direction,
all of the respective parts of the first coupling terminal, the second coupling terminal, and the third coupling terminal are led out of the package from the first end, and
θ ranges from 0° to 90°,
where
the package is projected onto a plane that is perpendicular to the rotational axis from an infinite distance of the rotational axis,
a line segment that connects the rotational axis to a position at which the first coupling terminal is coupled to the first electrode is a first line segment,
a line segment that connects the rotational axis to a position at which the third coupling terminal is coupled to the second electrode is a second line segment, and
θ denotes a minor angle formed between the first line segment and the second line segment.

4. The capacitor according to claim 3, wherein, the third coupling terminal is coupled to a position of the second electrode that is adjacent, within the range of the angle θ, to a coupling position of the first electrode to the first coupling terminal, where the package is projected onto the plane that is perpendicular to the rotational axis from the infinite distance of the rotational axis.

5. The capacitor according to claim 1, further comprising a fourth coupling terminal coupled to the first electrode and having a part that is led out of the package.

6. The capacitor according to claim 5, wherein
the package includes
a first end located in a first direction of the rotational axis as viewed from an inside of the package, and
a second end located in a second direction of the rotational axis as viewed from the inside of the package, the second direction being different from the first direction,
the part of the first coupling terminal and the part of the third coupling terminal are each led out of the package from the first end, and
the part of the second coupling terminal and the part of the fourth coupling terminal are each led out of the package from the second end.

7. The capacitor according to claim 1, wherein the first coupling terminal and the third coupling terminal are twisted together partially and electrically insulated from each other.

8. The capacitor according to claim 5, wherein the second coupling terminal and the fourth coupling terminal are twisted together partially and electrically insulated from each other.

9. A substrate module comprising:
the capacitor according to claim 1; and
a mounting substrate that includes a first power supply layer and a second power supply layer.

10. The substrate module according to claim 9, wherein
the part of the first coupling terminal is coupled to one of the first power supply layer and the second power supply layer, and
the part of the second coupling terminal and the part of the third coupling terminal are each coupled to the other of the first power supply layer and the second power supply layer.

11. A capacitor comprising:
a package;
a first electrode and a second electrode that face each other and spaced apart from each other to avoid mutual contact, the first electrode and the second electrode being each wound in an eddy shape around a rotational axis inside the package;
a first coupling terminal coupled to the first electrode and having a part that is led out of the package;
a second coupling terminal coupled to the second electrode and having a part that is led out of the package; and
a third coupling terminal that is coupled to an intermediate part of the first coupling terminal, and extends from the intermediate part of the first coupling terminal in a direction that is different from an extending direction of the first coupling terminal, the third coupling terminal having a part that is led out of the package after extending from the intermediate part.

12. The capacitor according to claim 11, wherein
the package includes
a first end located in a first direction of the rotational axis as viewed from an inside of the package, and
a second end located in a second direction of the rotational axis as viewed from the inside of the package, the second direction being different from the first direction,
the part of the first coupling terminal is led out of the package from the first end, and
the part of the second coupling terminal and the part of the third coupling terminal are each led out of the package from the second end.

13. The capacitor according to claim 11, further comprising a fourth coupling terminal that is coupled to an intermediate part of the second coupling terminal, and extends from the intermediate part of the second coupling terminal in a direction that is different from an extending direction of the second coupling terminal, the fourth coupling terminal having a part that is led out of the package after extending from the intermediate part.

14. The capacitor according to claim 13, wherein
the package includes
a first end located in a first direction of the rotational axis as viewed from an inside of the package, and
a second end located in a second direction of the rotational axis as viewed from the inside of the package, the second direction being different from the first direction,
the part of the first coupling terminal and the part of the fourth coupling terminal are each led out of the package from the first end, and
the part of the second coupling terminal and the part of the third coupling terminal are each led out of the package from the second end.

15. The capacitor according to claim 12, wherein the second coupling terminal and the third coupling terminal are twisted together partially and electrically insulated from each other.

16. The capacitor according to claim 14, wherein the first coupling terminal and the fourth coupling terminal are twisted together partially and electrically insulated from each other.

17. A substrate module comprising:
the capacitor according to claim 11; and
a mounting substrate that includes a first power supply layer and a second power supply layer.

18. The substrate module according to claim 17, wherein
the part of the first coupling terminal and the part of the third coupling terminal are each coupled to one of the first power supply layer and the second power supply layer, and
the part of the second coupling terminal is coupled to the other of the first power supply layer and the second power supply layer.

19. A capacitor comprising:
a package;
a first electrode and a second electrode that face each other and spaced apart from each other to avoid mutual contact, the first electrode and the second electrode being each wound in an eddy shape around a rotational axis inside the package;
a first coupling terminal coupled to the first electrode and having a part that is led out of the package;
a second coupling terminal coupled to the second electrode and having a part that is led out of the package; and
a third coupling terminal and a fourth coupling terminal that are coupled to each other inside the package, with a part of the third coupling terminal and a part of the fourth coupling terminal being each led out of the package.

20. The capacitor according to claim 19, wherein
the package includes
a first end located in a first direction of the rotational axis as viewed from an inside of the package, and
a second end located in a second direction of the rotational axis as viewed from the inside of the package, the second direction being different from the first direction,
the part of the first coupling terminal and the part of the third coupling terminal are each led out of the package from the first end, and
the part of the second coupling terminal and the part of the fourth coupling terminal are each led out of the package from the second end.

21. The capacitor according to claim 20, wherein coupling terminals of one or both of a first combination and a second combination are twisted together partially and electrically insulated from each other, the first combination including the first coupling terminal and the third coupling terminal, the second combination including the second coupling terminal and the fourth coupling terminal.

22. A substrate module comprising:
the capacitor according to claim 19; and
a mounting substrate that includes a first power supply layer and a second power supply layer.

23. The substrate module according to claim 22, wherein
the part of the first coupling terminal is coupled to one of the first power supply layer and the second power supply layer,
the part of the second coupling terminal is coupled to the other of the first power supply layer and the second power supply layer, and
the part of the third coupling terminal and the part of the fourth coupling terminal are each coupled to a same power supply layer of the first power supply layer and the second power supply layer.
